(19) United States
(12) Patent Application Publication
(10) Pub. No.: US 2018/0025918 A1
(43) Pub. Date: Jan. 25, 2018

(54) METHOD FOR MANUFACTURING TRANSISTOR AND DISPLAY DEVICE

(71) Applicant: Semiconductor Energy Laboratory Co., Ltd., Atsugi-shi (JP)

(72) Inventors: Shunpei YAMAZAKI, Setagaya (JP); Takashi HAMOCHI, Tochigi (JP); Yasuharu HOSAKA, Tochigi (JP); Toshimitsu OBONAI, Shimotsuke (JP)

(73) Assignee: Semiconductor Energy Laboratory Co., Ltd.

(21) Appl. No.: 15/654,089

(22) Filed: Jul. 19, 2017

(30) Foreign Application Priority Data
Jul. 25, 2016 (JP) 2016-145308

(51) Int. Cl. H01L 21/3213; H01L 21/18; H01L 29/49; H01L 29/812; H01L 21/28

(52) U.S. Cl. CPC H01L 21/32137; H01L 29/812; H01L 21/2807; H01L 21/28079; H01L 29/495; H01L 29/4966; H01L 21/18; H01L 21/28035

(57) ABSTRACT

A transistor with high productivity and a method for manufacturing the transistor are provided. In the formation of a bottom-gate transistor using a metal oxide layer as a semiconductor layer where a channel is formed, a gate insulating layer including silicon nitride is formed, and then plasma treatment is successively performed in the same treatment chamber under an atmosphere containing oxygen. After that, the metal oxide layer is formed.

### TECHNICAL FIELD

The present invention relates to an object, a method, or a manufacturing method. The present invention relates to a process, a machine, manufacture, or a composition of matter. One embodiment of the present invention relates to a semiconductor device, a display device, a light-emitting device, a lighting device, a power storage device, a memory device, a processor, a driving method thereof, or a manufacturing method thereof. In particular, one embodiment of the present invention relates to a semiconductor device, a display device, or a light-emitting device each including a metal oxide.

In this specification and the like, a semiconductor device generally means a device that can function by utilizing semiconductor characteristics. A display device, a light-emitting device, a lighting device, an electro-optical device, a semiconductor circuit, and an electronic device include a semiconductor device in some cases.

### BACKGROUND ART

Silicon is known as a material used for a semiconductor layer of a transistor; either amorphous silicon or polycrystalline silicon is used depending on the purpose. For example, when silicon is used for a semiconductor layer of a transistor included in a large-sized display device, it is preferable to use amorphous silicon, which can be formed using the established technique for forming a film on a large-sized substrate. On the other hand, when silicon is used for a semiconductor layer of a transistor included in a high-performance display device in which a display portion and a driver circuit are formed over one substrate, it is preferable to use polycrystalline silicon, which can achieve a transistor with high field-effect mobility.

Meanwhile, an oxide semiconductor, which is one kind of metal oxide, has attracted attention recently as a material used for a semiconductor layer of a transistor. For example, a transistor using an amorphous oxide semiconductor containing indium, gallium, and zinc is known (see Patent Document 1).

An oxide semiconductor that is one kind of metal oxide can be formed by a sputtering method or the like, and thus can be used for a semiconductor layer of a transistor in a large display device. In addition, capital investment can be reduced because part of production equipment for a transistor including amorphous silicon can be retrofitted and utilized. A transistor including an oxide semiconductor that is one kind of metal oxide has high field-effect mobility; therefore, a high-performance display device in which a display portion and a driver circuit are formed over one substrate can be obtained.

It is also known that a transistor in which an oxide semiconductor that is one kind of metal oxide is used for a semiconductor layer has an extremely low leakage current in an off state. For example, a low power consumption CPU and the like utilizing a characteristic of a low leakage current of the transistor including an oxide semiconductor are disclosed (see Patent Document 2).

### REFERENCE

### Patent Document

### [Patent Document 1] Japanese Published Patent Application No. 2006-165528

### [Patent Document 2] Japanese Published Patent Application No. 2012-257187

### DISCLOSURE OF INVENTION

An object of one embodiment of the present invention is to provide a transistor with favorable electrical characteristics. Another object is to provide a method for manufacturing a transistor with favorable electrical characteristics. Another object is to provide a transistor with low power consumption. Another object is to provide a method for manufacturing a transistor with low power consumption. Another object is to provide a transistor with high reliability. Another object is to provide a method for manufacturing a transistor with high reliability. Another object is to provide a novel transistor. Another object is to provide a method for manufacturing a novel transistor. Another object is to provide a semiconductor device including at least one of these transistors.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention is a method for manufacturing a transistor, which includes a first step including a step of forming a gate electrode, a second step including a step of forming a gate insulating layer over the gate electrode, a third step including a step of exposing a surface of the gate insulating layer to an atmosphere containing an oxygen ion or an oxygen radical, a fourth step including a step of forming a metal oxide layer over the gate insulating layer, and a fifth step including a step of forming a source electrode and a drain electrode over the metal oxide layer. The gate insulating layer includes silicon and nitrogen, and the second step and the third step are performed in one treatment chamber.

It is preferable that the second step and the third step be performed successively under a reduced pressure atmosphere. It is preferable that the third step be plasma treatment performed under an atmosphere containing oxygen.

The metal oxide layer can function as an oxide semiconductor. The metal oxide layer preferably includes at least one of indium and zinc. The metal oxide layer preferably includes a metal matrix composite.

Another embodiment of the present invention is a display device which includes a transistor formed by the above described manufacturing method, a first display element, and a second display element. The first display element is configured to reflect visible light, and the second display element is configured to emit visible light.

According to one embodiment of the present invention, a transistor with favorable electrical characteristics can be provided. A method for manufacturing a transistor with favorable electric characteristics can be provided. A transistor with low power consumption can be provided. A method for manufacturing a transistor with low power consumption can be provided. A transistor with high reliability can be provided. A method for manufacturing a transistor with high reliability can be provided. A novel transistor can be provided. A method of manufacturing a novel transistor can be provided. A semiconductor device including at least one of these transistors can be provided.

Note that the description of these effects does not preclude the existence of other effects. One embodiment of the present invention does not have to have all the effects listed above. Other effects will be apparent from and can be derived from the description of the specification, the drawings, the claims, and the like.

### BRIEF DESCRIPTION OF DRAWINGS

FIGS. 1A to 1C illustrate a transistor.

FIGS. 2A and 2B illustrate a transistor.

FIGS. 3A to 3C illustrate a transistor.

FIGS. 4A to 4D illustrate a method for manufacturing a transistor.

FIGS. 5A to 5D illustrate a method for manufacturing a transistor.

FIGS. 6A to 6C illustrate a method for manufacturing a transistor.

FIGS. 7A to 7C illustrate a method for manufacturing a transistor.

FIG. 8 illustrates a transistor.

FIGS. 9A to 9C illustrate a method for manufacturing a transistor.

FIGS. 10A to 10D illustrate a method for manufacturing a transistor.

FIG. 11A is a block diagram illustrating a display device, and FIGS. 11B and 11C are circuit diagrams each illustrating a pixel circuit.

FIGS. 12A and 12B are circuit diagrams each illustrating a pixel circuit.

FIGS. 13A and 13B are block diagrams each illustrating a driver circuit.

FIGS. 14A to 14C each illustrate one mode of the present invention.

FIGS. 15A and 15B illustrate one mode of the present invention.

FIGS. 16A, 16B1, and 16B2 illustrate one mode of the present invention.

FIG. 17 illustrates one mode of the present invention.

FIGS. 18A and 18B illustrate one mode of the present invention.

FIG. 19 illustrates a display device.

FIG. 20 illustrates a display device.

FIG. 21 illustrates a display device.

FIG. 22 illustrates a display module.

FIGS. 23A to 23G illustrate electronic devices.

FIGS. 24A and 24B are graphs for describing Example.

FIGS. 25A and 25B are graphs for describing Example.

### BEST MODE FOR CARRYING OUT THE INVENTION

Embodiments and examples will be described in detail with reference to the drawings. Note that the present invention is not limited to the following description and it will be readily appreciated by those skilled in the art that modes and details can be modified in various ways without departing from the spirit and the scope of the present invention. Thus, the present invention should not be construed as being limited to the description in the following embodiments and example. Note that in the structures of the invention described below, the same portions or portions having similar functions are denoted by the same reference numerals in different drawings, and description of such portions is not repeated in some cases.

The position, size, range, and the like of each component illustrated in the drawings and the like are not accurately represented in some cases to facilitate understanding of the invention. Therefore, the present invention is not necessarily limited to the position, size, range, or the like as disclosed in the drawings and the like. For example, in the actual manufacturing process, a layer, a resist mask, or the like might be unintentionally reduced in size by treatment such as etching, which is not illustrated in some cases for easy understanding.

Especially in a top view (also referred to as a “plan view”), a perspective view, or the like, some components might not be illustrated for easy understanding of the invention. In addition, some hidden lines and the like might not be shown.

When two layers which are in contact with each other have similar compositions or crystal states, the interface between the layers is not clearly observed in some cases. Therefore, the interface between the two layers may be indicated by a dotted line in a drawing or the like.

Ordinal numbers such as “first” and “second” in this specification and the like are used in order to avoid confusion among components and do not denote the priority or the order such as the order of steps or the stacking order. A term without an ordinal number in this specification and the like might be provided with an ordinal number in a claim in order to avoid confusion among components. A term with an ordinal number in this specification and the like might be provided with a different ordinal number in a claim. Moreover, a term with an ordinal number in this specification and the like might not be provided with any ordinal number in a claim.

In addition, in this specification and the like, the term such as an “electrode” or a “wiring” does not limit a function of the component. For example, an “electrode” is used as part of a “wiring” in some cases, and vice versa. Further, the term “electrode” or “wiring” can also mean a combination of a plurality of “electrodes” and “wirings” provided in an integrated manner.

Note that the term “over” or “under” in this specification and the like does not necessarily mean that a component is placed “directly on” or “directly below” and “directly in contact with” another component. For example, the expression “electrode B over insulating layer A” does not necessarily mean that the electrode B is on and in direct contact with the insulating layer A and can mean the case where another component is provided between the insulating layer A and the electrode B.

Functions of a source and a drain might be switched depending on operation conditions, for example, when a transistor having opposite polarity is employed or the direction of current flow is changed in circuit operation. Thus, it is difficult to define which is a source or a drain. Accordingly, the terms “source” and “drain” can be switched in this specification.

Furthermore, in this specification and the like, an explicit description “X and Y are connected” means that X and Y are electrically connected, X and Y are functionally connected, and X and Y are directly connected. Accordingly, without being limited to a predetermined connection relationship, for example, a connection relationship shown in drawings or texts, another connection relationship is included in the drawings or the texts.

Note that in this specification and the like, the term “electrically connected” includes the case where components are connected through an object having any electric function. There is no particular limitation on the “object having any electric function” as long as electric signals can be transmitted and received between components that are connected through the object. Accordingly, even when the expression “electrically connected” is used in this specification, there is a case in which no physical connection is made and a wiring is just extended in an actual circuit.

Note that the channel length refers to, for example, the distance between a source (a source region or a source electrode) and a drain (a drain region or a drain electrode) in a region where a semiconductor (or a portion where a current flows in a semiconductor when a transistor is on) and a gate electrode overlap each other or a region where a channel is formed in a top view of the transistor. In one transistor, channel lengths in all regions are not necessarily the same. In other words, the channel length of one transistor is not fixed to one value in some cases. Therefore, in this specification, the channel length is any one of values, the maximum value, the minimum value, or the average value in a region where a channel is formed.

The channel width refers to, for example, the length of a portion where a source and a drain face each other in a region where a semiconductor (or a portion where a current flows in a semiconductor when a transistor is on) and a gate electrode overlap each other, or a region where a channel is formed. In one transistor, channel widths in all regions are not necessarily the same. In other words, the channel width of one transistor is not fixed to one value in some cases. Therefore, in this specification, the channel width is any one of values, the maximum value, the minimum value, or the average value in a region where a channel is formed.

Note that depending on transistor structures, a channel width in a region where a channel is actually formed (hereinafter referred to as an “effective channel width”) is different from a channel width shown in a top view of a transistor (hereinafter referred to as an “apparent channel width”) in some cases. For example, in a transistor having a gate electrode covering a side surface of a semiconductor layer, an effective channel width is greater than an apparent channel width, and its influence cannot be ignored in some cases. For example, in a miniaturized transistor having a gate electrode covering a side surface of a semiconductor, the proportion of a channel region formed in a side surface of a semiconductor is increased. In that case, an effective channel width is greater than an apparent channel width.

In such a case, an effective channel width is difficult to measure in some cases. For example, to estimate an effective channel width from a design value, it is necessary to assume that the shape of a semiconductor is known as an assumption condition. Therefore, in the case where the shape of a semiconductor is not known accurately, it is difficult to measure an effective channel width accurately.

Therefore, in this specification, an apparent channel width is referred to as a surrounded channel width (SCW) in some cases. Further, in this specification, in the case where the term “channel width” is simply used, it may represent a surrounded channel width or an apparent channel width. Alternatively, in this specification, in the case where the term “channel width” is simply used, it may represent an effective channel width in some cases. Note that a channel length, a channel width, an effective channel width, an apparent channel width, a surrounded channel width, and the like can be determined by analyzing a cross-sectional TEM image and the like.

Note that in the case where field-effect mobility, a current value per channel width, and the like of a transistor are obtained by calculation, a surrounded channel width may be used for the calculation. In that case, a value different from one in the case where an effective channel width is used for the calculation is obtained in some cases.

Note that the term “impurity” in a semiconductor refers to, for example, an element other than the main components of the semiconductor. For example, an element with a concentration lower than 0.1 atomic % can be regarded as an impurity. Inclusion of impurities may cause an increase in density of states (DOS) in a semiconductor, and/or a decrease in the carrier mobility or the crystallinity.

In this specification, the term “parallel” indicates that the angle formed between two straight lines is greater than or equal to −10° and less than or equal to 10°, and accordingly also includes the case where the angle is greater than or equal to −5° and less than or equal to 5°. In addition, the term “substantially parallel” indicates that the angle formed between two straight lines is greater than or equal to −30° and less than or equal to 30°. The terms “perpendicular” and “orthogonal” indicates that the angle formed between two straight lines is greater than or equal to 80° and less than or equal to 100°. Accordingly, the terms “perpendicular” and “orthogonal” includes the case where the angle formed between two straight lines is greater than or equal to 85° and less than or equal to 95°. In addition, the term “substantially perpendicular” indicates that the angle formed between two straight lines is greater than or equal to 60° and less than or equal to 120°.

In the specification and the like, the terms “identical”, “the same”, “equal”, “uniform”, and the like (including synonyms thereof) used in describing calculation values and actual measurement values allow for a margin of error of ±20% unless otherwise specified.

In this specification and the like, in the case where an etching step (removal step) is performed after a resist mask is formed in a photolithography method, the resist mask is removed after the etching step, unless otherwise specified.

In this specification and the like, a high power supply potential VDD (also referred to as VDD or H potential) is a power supply potential higher than a low power supply potential VSS (also referred to as VSS or L potential). The low power supply potential VSS is a power supply potential lower than the high power supply potential VDD. A ground potential (also referred to as “GND” or a “GND potential”) can be used as VDD or VSS. For example, in the case where a ground potential is used as VDD, VSS is lower than the ground potential, and in the case where a ground potential is used as VSS, VDD is higher than the ground potential.

Note that the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

In this specification and the like, a transistor is an element having at least three terminals of a gate, a drain, and a source. The transistor includes a channel formation region between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

A transistor described in this specification and the like refers to an enhancement-mode (normally-off) field-effect transistor, unless otherwise specified. A transistor described in this specification and the like also refers to an n-channel transistor, unless otherwise specified. Therefore, the threshold voltage (also referred to as “Vₜₕ”) thereof is higher than 0 V, unless otherwise specified.

Note that the Vₜₕ of a transistor including a back gate in this specification and the like refers to a Vₜₕ obtained when the potential of the back gate is set equal to that of a source or a gate, unless otherwise specified.

Unless otherwise specified, off-state current in this specification and the like refers to drain current of a transistor in an off state (also referred to as a non-conducting state and a cutoff state). Unless otherwise specified, the off state of an n-channel transistor means that a potential difference (hereinafter also referred to as V_{g}) between its gate and source when the potential of the source is regarded as a reference potential is lower than the threshold voltage Vₜₕ, and the off state of a p-channel transistor means that the voltage V_{g} between its gate and source is higher than the threshold voltage Vₜₕ. For example, the off-state current of an n-channel transistor sometimes refers to a drain current that flows when V_{g} is lower than the threshold voltage Vₜₕ.

The off-state current of a transistor depends on V_{g} in some cases. For this reason, when there is V_{g} at which the off-state current of a transistor is lower than or equal to I, it may be said that the off-state current of the transistor is lower than or equal to I. Furthermore, the off-state current of a transistor may refer to the off-state current in an off state at predetermined V_{g}, the off-state current in an off state at V_{g} in a predetermined range, the off-state current in an off state at V_{g} with which sufficiently reduced off-state current is obtained, or the like.

As an example, the assumption is made of an n-channel transistor where Vₜₕ is 0.5 V and the drain current is 1×10⁻⁹ A at V_{g} of 0.5 V, 1×10⁻¹³ A at V_{g} of 0.1 V, 1×10⁻¹⁹ A at V_{g} of −0.5 V, and 1×10⁻²² A at V_{g} of −0.8 V. The drain current of the transistor is lower than or equal to 1×10⁻¹⁹ A at V_{g} of −0.5 V or at V_{g} in the range of −0.8 V to −0.5 V; therefore, it can be said that the off-state current of the transistor is lower than or equal to 1×10⁻¹⁹ A. Since there is V_{g} at which the drain current of the transistor is lower than or equal to 1×10⁻²² A, it can be said that the off-state current of the transistor is lower than or equal to 1×10⁻²² A.

The off-state current of a transistor depends on temperature in some cases. Unless otherwise specified, the off-state current in this specification may be an off-state current at room temperature (RT), 60° C., 85° C., 95° C., or 125° C. Alternatively, the off-state current may be an off-state current at a temperature at which the reliability of a semiconductor device or the like including the transistor is ensured or a temperature at which the semiconductor device or the like is used (e.g., a temperature higher than or equal to 5° C. and lower than or equal to 35° C.). The state in which the off-state current of a transistor is lower than or equal to I may indicate that the off-state current of the transistor at RT, 60° C., 85° C., 95° C., 125° C., a temperature at which the reliability of a semiconductor device or the like including the transistor is ensured, or a temperature at which the semiconductor device or the like is used (e.g., a temperature higher than or equal to 5° C. and lower than or equal to 35° C.) is lower than or equal to I at a certain V_{g}.

In some cases, the off-state current of a transistor depends on a voltage between its drain and source when the potential of the source is regarded as a reference potential (hereinafter such a voltage is also referred to as V_{d}). Unless otherwise specified, the off-state current in this specification may be an off-state current at V_{d} of 0.1 V, 0.8 V, 1 V, 1.2 V, 1.8 V, 2.5 V, 3 V, 3.3 V, 10 V, 12 V, 16 V, or 20 V. Alternatively, the off-state current may be an off-state current at V_{d} at which the reliability of a semiconductor device or the like including the transistor is ensured or at V_{d} used in the semiconductor device or the like including the transistor. The state in which the off-state current of a transistor is lower than or equal to I may indicate that the off-state current of the transistor at V_{d} of 0.1 V, 0.8 V, 1 V, 1.2 V, 1.8 V, 2.5 V, 3 V, 3.3 V, 10 V, 12 V, 16 V, or 20 V, at V_{d} at which the reliability of a semiconductor device or the like including the transistor is ensured, or at V_{d} used in the semiconductor device or the like is lower than or equal to I at a certain V_{g}.

In the above description of off-state current, a drain may be replaced with a source. That is, the off-state current sometimes refers to a current that flows through a source of a transistor in the off state.

In this specification and the like, the term “leakage current” sometimes expresses the same meaning as “off-state current”. In this specification and the like, the off-state current sometimes refers to a current that flows between a source and a drain of a transistor in the off state, for example.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is called an oxide semiconductor in some cases. That is to say, a metal oxide that has at least one of an amplifying function, a rectifying function, and a switching function can be called a metal oxide semiconductor, or OS for short. In addition, an OS FET is a transistor including a metal oxide or an oxide semiconductor.

In this specification and the like, a metal oxide including nitrogen is also called a metal oxide in some cases. Moreover, a metal oxide including nitrogen may be called a metal oxynitride.

In this specification and the like, “c-axis aligned crystal (CAAC)” or “cloud-aligned composite (CAC)” might be stated. Note that CAAC refers to an example of a crystal structure, and CAC refers to an example of a function or a material composition.

In this specification and the like, a CAC-OS or a CAC metal oxide has a conducting function in a part of the material and has an insulating function in another part of the material; as a whole, the CAC-OS or the CAC metal oxide has a function of a semiconductor. In the case where the CAC-OS or the CAC metal oxide is used in an active layer of a transistor, the conducting function is to allow electrons (or holes) serving as carriers to flow, and the insulating function is to not allow electrons serving as carriers to flow. By the complementary action of the conducting function and the insulating function, the CAC-OS or the CAC metal oxide can have a switching function (on/off function). In the CAC-OS or CAC-metal oxide, separation of the functions can maximize each function.

In this specification and the like, the CAC-OS or the CAC metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. The conductive regions are observed to be coupled in a cloud-like manner with their boundaries blurred, in some cases.

Furthermore, in the CAC-OS or the CAC metal oxide, the conductive regions and the insulating regions each have a size of more than or equal to 0.5 nm and less than or equal to 10 nm, preferably more than or equal to 0.5 nm and less than or equal to 3 nm and are dispersed in the material, in some cases.

The CAC-OS or the CAC metal oxide includes components having different bandgaps. For example, the CAC-OS or the CAC metal oxide includes a component having a wide gap due to the insulating region and a component having a narrow gap due to the conductive region. In the case of such a composition, carriers mainly flow in the component having a narrow gap. The component having a narrow gap complements the component having a wide gap, and carriers also flow in the component having a wide gap in conjunction with the component having a narrow gap. Therefore, in the case where the above-described CAC-OS or the CAC metal oxide is used in a channel formation region of a transistor, high current drive capability in the on state of the transistor, that is, high on-state current and high field-effect mobility, can be obtained.

In other words, CAC-OS or CAC-metal oxide can be called a matrix composite or a metal matrix composite.

An oxide semiconductor, which is one type of metal oxide, is classified into a single crystal oxide semiconductor and a non-single-crystal oxide semiconductor. Examples of a non-single-crystal oxide semiconductor include a c-axis-aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

The CAAC-OS has c-axis alignment, its nanocrystals are connected in the a-b plane direction, and its crystal structure has distortion. Note that the distortion is a portion where the direction of a lattice arrangement changes between a region with a regular lattice arrangement and another region with a regular lattice arrangement in a region in which nanocrystals are connected.

The shape of the nanocrystal is basically hexagon. However, the shape is not always a regular hexagon and is a non-regular hexagon in some cases. A pentagonal lattice arrangement, a heptagonal lattice arrangement, and the like are included in the distortion in some cases. Note that a clear crystal grain boundary cannot be observed even in the vicinity of distortion in the CAAC-OS. That is, formation of a grain boundary is inhibited due to the distortion of lattice arrangement. This is probably because the CAAC-OS can tolerate distortion owing to a low density of arrangement of oxygen atoms in the a-b plane direction, an interatomic bond distance changed by substitution of a metal element, and the like.

The CAAC-OS tends to have a layered crystal structure (also referred to as a stacked-layer structure) in which a layer containing indium and oxygen (hereinafter, In layer) and a layer containing the element M, zinc, and oxygen (hereinafter, (M,Zn) layer) are stacked. When the element M in the (M,Zn) layer is replaced with indium, the layer can also be referred to as an (In,M,Zn) layer. Also, when indium in the In layer is replaced with the element M, the layer can be referred to as an (In,M) layer.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different nanocrystals in the nc-OS. Thus, the orientation of the whole film is not observed. Accordingly, the nc-OS cannot be distinguished from an a-like OS or an amorphous oxide semiconductor, depending on an analysis method.

An a-like OS has a structure intermediate between those of the nc-OS and the amorphous oxide semiconductor. The a-like OS includes a void or a low-density region. That is, the a-like OS has low crystallinity as compared with the nc-OS and the CAAC-OS.

An oxide semiconductor, which is one type of metal oxide, can have various structures which show various different properties. Two or more of the amorphous oxide semiconductor, the polycrystalline oxide semiconductor, the a-like OS, the nc-OS, and the CAAC-OS may be included in an oxide semiconductor that is used in one embodiment of the present invention. Furthermore, a CAC-OS may be included.

### Embodiment 1

A transistor 100 of one embodiment of the present invention is described with reference to drawings.

### <Structure Example of Transistor 100>

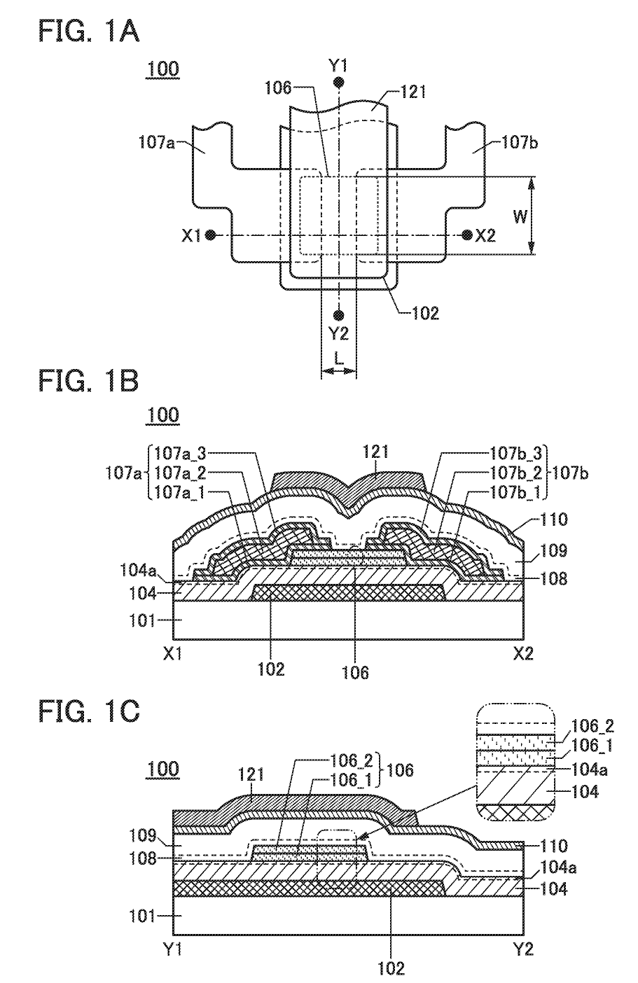

FIG. 1A illustrates a plan view of the transistor 100. FIG. 1B is a cross-sectional view of a portion indicated by the dashed-dotted line X1-X2 in FIG. 1A. FIG. 1C is a cross-sectional view of a portion indicated by the dashed-dotted line Y1-Y2 in FIG. 1A.

The transistor 100 is a bottom-gate transistor. The transistor 100 includes an electrode 102, an insulating layer 104, an oxide layer 104a, a semiconductor layer 106 (a semiconductor layer 106_1 and a semiconductor layer 106_2), an electrode 107a (an electrode 107a_1, an electrode 107a_2, and an electrode 107a_3), an electrode 107b (an electrode 107b_1, an electrode 107b_2, and an electrode 107b_3), an insulating layer 108, an insulating layer 109, an insulating layer 110, and an electrode 121.

The electrode 102 is provided over a substrate 101. The insulating layer 104 is provided to cover the electrode 102. The oxide layer 104a may be formed by a change in the composition of a surface of the insulating layer 104. Therefore, the oxide layer 104a can also be regarded as part of the insulating layer 104 substantially. The semiconductor layer 106 is provided over the oxide layer 104a. There is a region where the electrode 102 and the semiconductor layer 106 overlap each other with the insulating layer 104 positioned therebetween.

The electrode 107a and the electrode 107b are provided over the insulating layer 104. The electrode 107a has a region which overlaps part of the semiconductor layer 106, and the electrode 107b has a region which overlaps another part of the semiconductor layer 106.

The insulating layer 108 is provided to cover the electrode 107a, the electrode 107b, and the semiconductor layer 106. The insulating layer 109 is provided over the insulating layer 108. The insulating layer 110 is provided over the insulating layer 109.

Although a two-layer structure of the insulating layers 108 and 109 is described in this embodiment, one embodiment of the present invention is not limited thereto; for example, a single-layer structure of either the insulating layer 108 or the insulating layer 109 or a stacked-layer structure including three or more layers may be employed.

The electrode 121 is provided over the insulating layer 110. The electrode 121 has a region which overlaps the electrode 102 with the semiconductor layer 106 positioned therebetween. The electrode 121 may be provided between the insulating layer 109 and the insulating layer 110.

In FIG. 1A, a channel length L and a channel width W of the transistor 100 are shown. The channel length L of the transistor 100 refers to a distance between the electrode 107a and the electrode 107b in a region where the semiconductor layer 106 and the electrode 102 overlap each other in the top view. The channel length W of the transistor 100 refers to the length of a portion where the electrode 107a and the electrode 107b face each other in a region where the semiconductor layer 106 and the electrode 102 overlap each other in the top view.

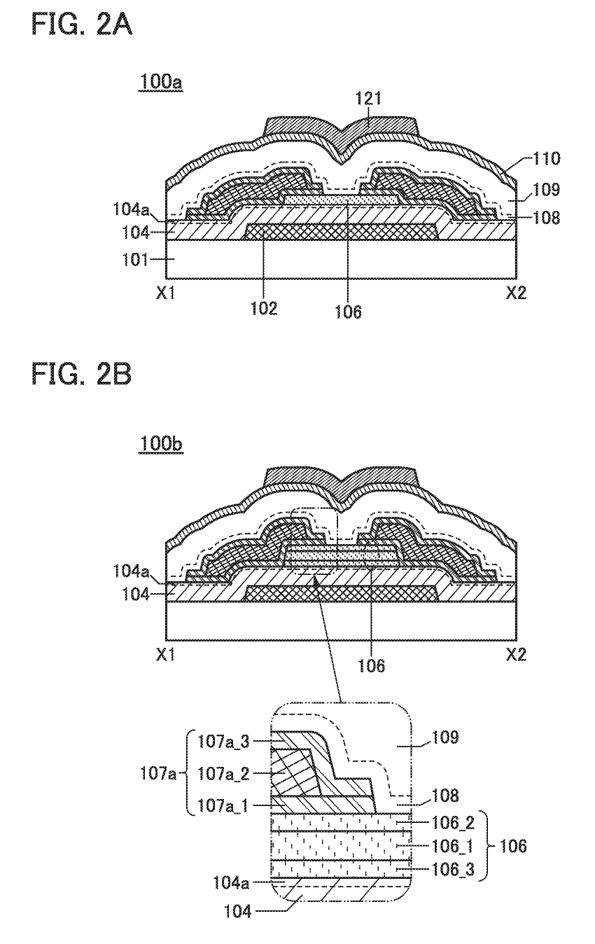

Although the semiconductor layer 106 illustrated in FIGS. 1B and 1C is a stack of two layers, the semiconductor layers 106_1 and 106_2, one embodiment of the present invention is not limited thereto. For example, the semiconductor layer 106 may be a single layer, as in a transistor 100a illustrated in FIG. 2A. Alternatively, the semiconductor layer 106 may have a three-layer structure of the semiconductor layer 106_1, the semiconductor layer 106_2, and a semiconductor layer 106_3, as in a transistor 100b illustrated in FIG. 2B. The semiconductor layer 106 may be a stack of four or more layers. Note that FIGS. 2A and 2B are cross-sectional views each corresponding to FIG. 1B. The transistor 100a and the transistor 100b each have the same structure as the transistor 100 except for the stacked-layer structure of the semiconductor layer 106.

The semiconductor layer 106_3 can be formed using a material and a method similar to those for the semiconductor layer 106_1 or the semiconductor layer 106_2.

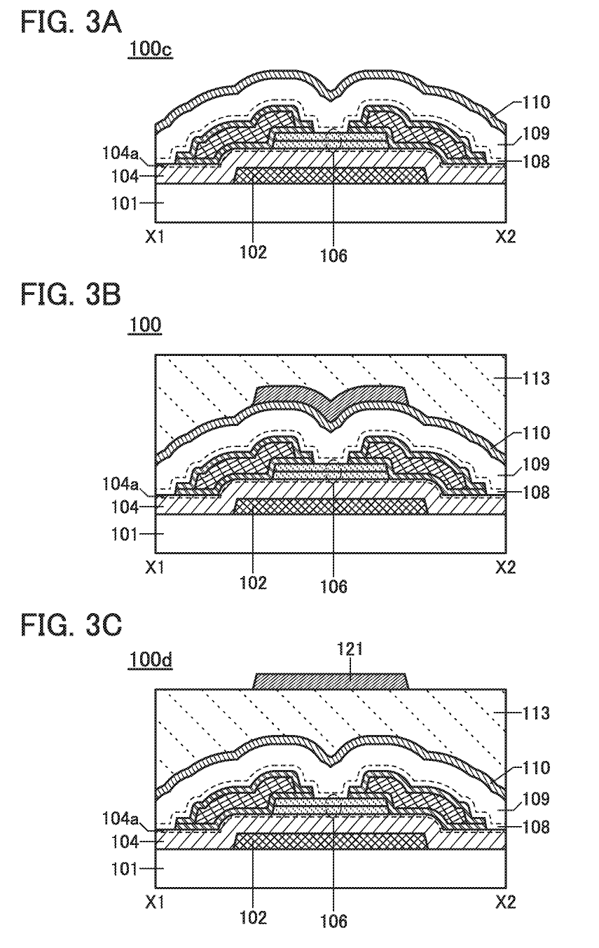

The electrode 121 is not provided in some cases, as in a transistor 100c illustrated in FIG. 3A. The transistor 100c has the structure of the transistor 100 without the electrode 121. An insulating layer 113 with a flat surface may be provided over the electrode 121 and the insulating layer 110 as illustrated in FIG. 3B. Alternatively, the insulating layer 113 may be provided between the electrode 121 and the insulating layer 110, as in a transistor 100d illustrated in FIG. 3C. The other components of the transistor 100d are similar to those of the transistor 100. Note that FIGS. 3A to 3C are cross-sectional views each corresponding to FIG. 1B.

### [Gate Electrode and Back Gate Electrode]

The electrode 102 and the electrode 121 each can function as a gate electrode. When one of the electrode 102 and the electrode 121 is referred to as a gate electrode, the other thereof is referred to as a back gate electrode. In addition, when one of the electrode 102 and the electrode 121 is referred to as a gate, the other thereof is referred to as a back gate. Note that the gate electrode may be referred to as a front gate. Similarly, the gate may be referred to as a front gate.

For example, when the electrode 102 in the transistor 100 illustrated in FIGS. 1A to 1C is referred to as a gate electrode, the electrode 121 is referred to as a back gate electrode. When the electrode 121 is used as the gate electrode, the transistor 100 can be considered as a top-gate transistor. In some cases, one of the electrodes 102 and 121 is referred to as a first gate electrode and the other is referred to as a second gate electrode.

The gate electrode and the back gate electrode are generally formed using conductive layers. The gate electrode and the back gate electrode are placed so that a channel formation region of the semiconductor layer is sandwiched therebetween. Such a structure enables the semiconductor layer 106 in the transistor 100 to be electrically surrounded by an electric field generated from the electrode 102 functioning as the gate electrode and an electric field generated from the electrode 121 functioning as the back gate electrode. Such a transistor structure in which electric fields generated from the gate electrode and the back gate electrode electrically surround the semiconductor layer where the channel is formed can be referred to as a surrounded-channel (S-channel) structure.

The back gate electrode can function in a manner similar to that of the gate electrode. The potential of the back gate electrode may be the same as that of the gate electrode or may be a ground potential or a predetermined potential. By changing the potential of the back gate electrode independently of the potential of the gate electrode, the threshold voltage of the transistor can be changed.

As described above, both the electrodes 102 and 121 can function as the gate electrode. Thus, the insulating layers 104, 108, 109, and 110 can function as gate insulating layers.

By providing the electrodes 102 and 121 so that the semiconductor layer 106 is positioned therebetween, and by setting the potentials of the electrodes 102 and 121 to be the same, a region of the semiconductor layer 106 through which carriers flow is enlarged in the film thickness direction; thus, the amount of transferred carriers is increased. As a result, the on-state current and the field-effect mobility of the transistor are increased.

Accordingly, the transistor can have a large on-state current for its area. That is, the area occupied by the transistor can be small for a required on-state current. Therefore, a semiconductor device having a high degree of integration can be provided.

Furthermore, the gate electrode and the back gate electrode are formed using conductive layers and thus each have a function of preventing an electric field generated outside the transistor from influencing the semiconductor layer in which the channel is formed (in particular, an electric field blocking function against static electricity and the like). When the back gate electrode is formed larger than the semiconductor layer to cover the semiconductor layer in the plan view, the electric field blocking function can be enhanced.

Since each of the electrodes 102 and 121 has a function of blocking an electric field from the outside, charges of charged particles and the like generated above the electrode 121 and below the electrode 102 do not influence the channel formation region of the semiconductor layer 106. Thus, degradation of electrical characteristics induced by a stress test, e.g., a negative gate bias temperature (NGBT) stress test where negative voltage is applied to a gate (this stress test is also referred to as NBT or NBTS) can be reduced. In addition, the electrodes 102 and 121 can block an electric field generated from the drain electrode so as not to affect the semiconductor layer. Thus, changes in the rising voltage of on-state current due to changes in drain voltage can be suppressed. Note that this effect is significant when a potential is supplied to the electrodes 102 and 121.

Before and after a positive gate bias temperature (PGBT) stress test where positive voltage is applied to a gate (this stress test is also referred to as PBT or PBTS)), a transistor including a back gate electrode has a smaller change in threshold voltage than a transistor including no back gate electrode.

The BT stress test such as NGBT or PGBT is a kind of accelerated test and can evaluate, in a short time, a change by long-term use (i.e., a change over time) in characteristics of transistors. In particular, the amount of a change in threshold voltage of the transistor between before and after the BT stress test is an important indicator when examining the reliability of the transistor. If the amount of a change in the threshold voltage between before and after the BT stress test is small, the transistor has higher reliability.

By providing the electrodes 102 and 121 and setting the potentials of the electrodes 102 and 121 to be the same, the change in threshold voltage is reduced. Accordingly, variation in electrical characteristics among a plurality of transistors is also reduced.

In the case where light is incident on the back gate electrode side, when the back gate electrode is formed using a light-blocking conductive film, light can be prevented from entering the semiconductor layer from the back gate electrode side. Therefore, photodegradation of the semiconductor layer can be prevented and deterioration in electrical characteristics of the transistor, such as a shift of the threshold voltage, can be prevented.

One of the electrodes 107a and 107b can function as one of a source electrode and a drain electrode. The other of the electrodes 107a and 107b can function as the other of the source electrode and the drain electrode.

### [Substrate]

There is no great limitation on a material used for the substrate 101. The material is determined according to the purpose in consideration of whether it has a light-transmitting property, heat resistance high enough to withstand heat treatment, or the like. As the substrate 101, a glass substrate, a ceramic substrate, a flexible substrate that has high heat resistance enough to withstand a process temperature of this manufacturing process, or the like can be used. In the case where a substrate does not need a light-transmitting property, a substrate in which an insulating layer is provided on a surface of a substrate of a metal such as a stainless steel alloy may be used. As the glass substrate, for example, an alkali-free glass substrate of barium borosilicate glass, aluminoborosilicate glass, aluminosilicate glass, or the like may be used. In addition, a quartz substrate, a sapphire substrate, or the like can be used.

As the glass substrate 101, a glass substrate having any of the following sizes can be used: the 3rd generation (550 mm×650 mm), the 3.5th generation (600 mm×720 mm or 620 mm×750 mm), the 4th generation (680 mm×880 mm or 730 mm×920 mm), the 5th generation (1100 mm×1300 mm), the 6th generation (1500 mm×1850 mm), the 7th generation (1870 mm×2200 mm), the 8th generation (2200 mm×2400 mm), the 9th generation (2400 mm×2800 mm or 2450 mm×3050 mm), and the 10th generation (2950 mm×3400 mm).

When a flexible substrate is used as the substrate 101, a transistor, a capacitor, and the like may be directly formed over the flexible substrate, or they may be formed over a manufacturing substrate, and then separated from the manufacturing substrate and transferred onto the flexible substrate. To separate and transfer the transistor, the capacitor, or the like from the manufacturing substrate to the flexible substrate, a separation layer may be provided between the manufacturing substrate and the transistor, the capacitor, or the like.

For the flexible substrate, for example, metal, an alloy, resin, glass, or fiber thereof can be used. The flexible substrate used as the substrate 101 preferably has a lower coefficient of linear expansion because deformation due to an environment is suppressed. The flexible substrate used as the substrate 101 is preferably formed using, for example, a material whose coefficient of linear expansion is lower than or equal to 1×10⁻³/K, lower than or equal to 5×10⁻⁵/K, or lower than or equal to 1×10⁻⁵/K.

Examples of a resin material used for the flexible substrate include polyethylene terephthalate (PET), polyethylene naphthalate (PEN), polyether sulfone (PES), polytetrafluoroethylene (PTFE), polypropylene, polyester, polyvinyl fluoride, polyvinyl chloride, polyolefin, polyamide (e.g., nylon or aramid), polyimide, polycarbonate, aramid, an epoxy-based resin, and an acrylic-based resin.

As the substrate 101, a single crystal semiconductor substrate or a polycrystalline semiconductor substrate made of silicon, silicon carbide, or the like or a compound semiconductor substrate made of silicon germanium or the like can also be used. Alternatively, an SOI substrate, a semiconductor substrate on which a semiconductor element such as a strained transistor or a FIN-type transistor is provided, or the like can also be used. Alternatively, gallium arsenide, aluminum gallium arsenide, indium gallium arsenide, gallium nitride, indium phosphide, silicon germanium, or the like that can be used for a high-electron-mobility transistor (HEMT) may be used. The substrate 101 is not limited to a simple supporting substrate, and may be a substrate where a device such as a transistor is formed. In that case, at least one of the gate, the source, and the drain of the transistor of one embodiment of the present invention may be electrically connected to the device.

### [Insulating Layer]

The insulating layers 104, 108, 109, and 110 can be formed with a single layer or a stack of layers of one or more inorganic materials selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, and aluminum silicate. Alternatively, a material in which two or more materials selected from an oxide material, a nitride material, an oxynitride material, and a nitride oxide material are mixed may be used.

Note that in this specification, a nitride oxide refers to a compound that includes more nitrogen than oxygen. An oxynitride refers to a compound that includes more oxygen than nitrogen. The content of each element can be measured by Rutherford backscattering spectrometry (RBS), for example.

In particular, the insulating layers 104 and 110 are preferably formed using an insulating material which is relatively impermeable to impurities. Examples of such an insulating material that is relatively impermeable to impurities include aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride.

When the insulating material that is relatively impermeable to impurities is used for the insulating layer 104, impurity diffusion from the substrate 101 side to the semiconductor layer 106 can be prevented, and the reliability of the transistor can be improved. When the insulating material that is relatively impermeable to impurities is used for the insulating layer 110, impurity diffusion from layers above the insulating layer 110 to the semiconductor layer 106 can be prevented, and the reliability of the transistor can be improved.

Moreover, the insulating layers 104 and 110 are preferably formed using an insulating material into which oxygen is less likely to diffuse and/or be absorbed. In that case, diffusion of oxygen to the outside can be suppressed.

Note that each of the insulating layers 104 and 110 may be a stack of insulating layers formed with these materials.

The hydrogen concentrations of the insulating layers are preferably lowered in order to prevent an increase in the hydrogen concentration of the semiconductor layer 106. In particular, the hydrogen concentration of the vicinity of an interface between the semiconductor layer 106 and the insulating layer in contact with the semiconductor layer 106 is preferably reduced. In this embodiment, for example, the hydrogen concentrations of the insulating layers 104 and 108 are preferably low. Specifically, the hydrogen concentration of the insulating layer that is measured by secondary ion mass spectrometry (SIMS) is lower than or equal to 2×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³.

At least one of the insulating layers 108 and 109 is preferably formed using an insulating layer from which oxygen is released by heating. Specifically, it is preferable to use an insulating layer in which the amount of released oxygen converted into oxygen atoms is greater than or equal to 1.0×10¹⁸ atoms/cm³, further preferably greater than or equal to 1.0×10¹⁹ atoms/cm³, or still further preferably greater than or equal to 1.0×10²⁰ atoms/cm³ in thermal desorption spectroscopy (TDS) where heat treatment is performed such that the surface temperature of the insulating layer ranges from 100° C. to 700° C., preferably from 100° C. to 500° C. Note that in this specification and the like, oxygen released by heating is also referred to as excess oxygen.

In particular, when an oxide semiconductor that is one kind of metal oxide is used as the semiconductor layer 106, the amount of defects in the insulating layer in contact with the semiconductor layer 106 is preferably small. Typically, the spin density of a signal that appears at g=2.001 due to a dangling bond of silicon is preferably lower than or equal to 3×10¹⁷ spins/cm³ by electron spin resonance (ESR) measurement. If the amount of defects in the insulating layer is large, oxygen might be bonded to the defects, reducing excess oxygen.

It is particularly preferable that the insulating layer in contact with the layer formed using an oxide semiconductor that is one kind of metal oxide be an insulating layer in which the density of states due to nitrogen oxide (NOx, where X is greater than 0 and less than or equal to 2; typically NO or NO₂) is low. As the insulating layer, a silicon oxynitride layer that releases less nitrogen oxide, an aluminum oxynitride layer that releases less nitrogen oxide, or the like can be used. An insulating layer that releases less nitrogen oxide is a layer in which the amount of released ammonia is larger than the amount of released nitrogen oxide in TDS; the amount of released ammonia is typically greater than or equal to 1×10¹⁸ molecules/cm³ and less than or equal to 5×10¹⁹ molecules/cm³. Note that the amount of released ammonia is the amount of ammonia released by heat treatment which makes the surface temperature of the insulating layer higher than or equal to 50° C. and lower than or equal to 650° C., preferably higher than or equal to 50° C. and lower than or equal to 550° C.

Nitrogen oxide forms a level in a metal oxide layer or an insulating layer. The level is positioned in the energy gap of the metal oxide. When nitrogen oxide reaches the interface between the insulating layer and the metal oxide layer, an electron can potentially be trapped by the level on the insulating layer side. As a result, the trapped electrons remain in the vicinity of the interface between the insulating layer and the metal oxide layer; thus, the threshold voltage of the transistor is shifted in the positive direction.

Note that the density of states due to the nitrogen oxide can be formed between the energy of the valence band maximum (Ev_os) and the energy of the conduction band minimum (Ec_os) of the metal oxide layer.

Nitrogen oxide reacts with ammonia and oxygen in heat treatment. Since nitrogen oxide contained in the insulating layer reacts with ammonia contained in the insulating layer in heat treatment, the nitrogen oxide contained in the insulating layer is reduced. Consequently, electrons are hardly trapped at the interface between the insulating layer and the metal oxide layer.

By using the above oxide insulating layer as the insulating layer in contact with the metal oxide layer, a shift in the threshold voltage of the transistor or the like can be reduced, which leads to reduced fluctuations in the electrical characteristics of the transistor.

An insulating layer which contains a large amount of a nitride material is relatively impermeable to impurities. It was difficult to obtain favorable electrical characteristics in a transistor in which a metal oxide layer functioning as a semiconductor is provided over an insulating layer containing a large amount of a nitride material. With one embodiment of the present invention described in this specification and the like, favorable electrical characteristics can be achieved even in a transistor in which a metal oxide layer is provided over an insulating layer containing a large amount of a nitride material. For example, favorable electrical characteristics can be achieved in a transistor in which a metal oxide layer is provided over a silicon nitride layer.

The insulating layer containing excess oxygen can also be formed by performing treatment for adding oxygen to an insulating layer. The treatment for adding oxygen can be performed by, an ion implantation method, an ion doping method, a plasma immersion ion implantation method, or the like. The treatment for adding oxygen can be heat treatment under an oxidation atmosphere, plasma treatment, inverse sputtering treatment, or the like. The plasma treatment under an oxidation atmosphere is preferably performed using an apparatus including a power source for generating high-density plasma using microwaves, for example. Alternatively, a power source for applying a radio frequency (RF) to a substrate side may be provided. Oxygen radicals at a high density can be generated with high-density plasma. Application of RF to the substrate side allows the oxygen radicals generated by the high-density plasma to be efficiently guided into a target layer. Alternatively, plasma treatment may be performed under an inert atmosphere and then plasma treatment may be performed under an oxidation atmosphere to compensate released oxygen. Oxygen addition through inverse sputtering treatment can bring about an effect of cleaning a sample surface. Meanwhile, damage might occur on the sample surface depending on treatment conditions. As a gas for adding oxygen, an oxygen gas of ¹⁶O₂, ¹⁸O₂, or the like, a nitrous oxide gas, an ozone gas, or the like can be used. In this specification, the treatment for adding oxygen is also referred to as “oxygen doping treatment”.

Note that the “oxidization atmosphere” refers to an atmosphere containing an oxidation gas such as oxygen, ozone, or nitrogen oxide at 10 ppm or higher. In addition, the “inert atmosphere” refers to an atmosphere that includes the oxidation gas at lower than 10 ppm and is filled with nitrogen or a rare gas.

Such oxygen doping treatment sometimes increases the crystallinity of the semiconductor layer. Furthermore, the oxygen doping treatment sometimes removes impurities contained in the target layer, such as hydrogen and water. That is, “oxygen doping treatment” can also be referred to as “impurity-removing treatment”. Specifically, plasma treatment performed using oxygen under a reduced pressure and an oxidizing atmosphere as the oxygen doping treatment cuts a bond involving hydrogen or water in a target insulating layer or a target semiconductor layer. This makes it easy for hydrogen and water in the target layer to be released. Thus, the plasma treatment as the oxygen doping treatment is preferably performed while heating is performed. Alternatively, heat treatment is preferably performed after the plasma treatment. When plasma treatment is performed after heat treatment and heat treatment is further performed, the impurity concentration in the target layer can be lowered.

The insulating layer 113 preferably has a function of covering unevenness and the like caused by the transistor or the like. The insulating layer 113 is formed using an insulating material. Accordingly, the insulating layer 113 can be formed using any of the above-described inorganic and organic materials. For example, the insulating layer 113 can be formed using a heat-resistant organic resin (organic material) such as polyimide, an acrylic-based resin, a benzocyclobutene-based resin, polyamide, or an epoxy-based resin as well as the aforementioned inorganic material. Other than such organic materials, it is also possible to use a low-dielectric constant material (a low-k material), a siloxane-based resin, PSG (phosphosilicate glass), BPSG (borophosphosilicate glass), or the like. Note that the insulating layer 113 may be formed by stacking a plurality of insulating layers formed of any of these materials.

Note that the siloxane-based resin corresponds to a resin containing a Si—O—Si bond formed using a siloxane-based material as a starting material. The siloxane-based resin may include as a substituent an organic group (e.g., an alkyl group or an aryl group) or a fluoro group. In addition, the organic group may include a fluoro group.

There is no particular limitation on the method for forming the insulating layer 113, and any of the following methods appropriate for a material thereof can be used: a sputtering method, an SOG method, spin coating, dipping, spray coating, a droplet discharging method (e.g., an inkjet method), a printing method (e.g., screen printing or offset printing), or the like. When the baking step of the insulating layer 113 also serves as heat treatment for another layer, a transistor can be manufactured efficiently.

A surface of the insulating layer 113 may be subjected to chemical mechanical polishing (CMP) treatment (hereinafter also referred to as CMP treatment). By the CMP treatment, unevenness of the surface of the insulating layer 113 can be reduced, and coverage with an insulating layer or a conductive layer to be formed later can be increased. Note that the insulating layers 104, 108, 109, and 110 may be subjected to CMP treatment.

### [Conductive Layer]

As a conductive material for forming the conductive layers such as the electrodes 102, 107a_1, 107a_2, 107a_3, 107b_1, 107b_2, 107b_3, and 121, a material containing one or more metal elements selected from aluminum (Al), chromium (Cr), iron (Fe), copper (Cu), silver (Ag), gold (Au), platinum (Pt), tantalum (Ta), nickel (Ni), titanium (Ti), cobalt (Co), molybdenum (Mo), tungsten (W), hafnium (Hf), vanadium (V), niobium (Nb), manganese (Mn), magnesium (Mg), zirconium (Zr), beryllium (Be), and the like can be used. Alternatively, a semiconductor having a high electric conductivity typified by polycrystalline silicon including an impurity element such as phosphorus, or silicide such as nickel silicide may be used.

A Cu—X alloy film (X is Mn, Ni, Cr, Fe, Co, Mo, Ta, or Ti) may be used as the conductive material. A layer made of a Cu—X alloy can be processed with a wet etching process, resulting in lower manufacturing cost.

A conductive material containing the above metal element and oxygen may be used. A conductive material containing the above metal element and nitrogen may be used. For example, a conductive material containing nitrogen such as titanium nitride or tantalum nitride may be used. Indium tin oxide (ITO), indium zinc oxide, indium gallium zinc oxide, indium oxide containing tungsten oxide, indium zinc oxide containing tungsten oxide, indium oxide containing titanium oxide, indium tin oxide containing titanium oxide, indium tin oxide containing silicon oxide may be used. Indium gallium zinc oxide containing nitrogen may be used.

A stack of a plurality of conductive layers formed with the above materials may be used. For example, a stacked-layer structure formed using a material containing the above metal element and a conductive material containing oxygen may be used. Alternatively, a stacked-layer structure formed using a material containing the above metal element and a conductive material containing nitrogen may be used. Further alternatively, a stacked-layer structure formed using a material containing the above metal element, a conductive material containing oxygen, and a conductive material containing nitrogen may be used.

This embodiment shows an example where each of the electrodes 107a and 107b has a three-layer structure; however, one embodiment of the present invention is not limited thereto. Each of the electrodes 107a and 107b may have a single-layer structure or a two-layer structure. Alternatively, each of the electrodes 107a and 107b may have a stacked-layer structure of four or more layers.

When copper is used in each of the electrodes 107a and 107b in order to lower the resistances of the electrodes 107a and 107b, a conductive material into which copper does not diffuse easily is preferably provided between the electrode 107a and the semiconductor layer 106 and between the electrode 107b and the semiconductor layer 106. Copper, which is likely to diffuse into a semiconductor layer, might make the operation of a semiconductor device unstable to significantly reduce the yield. When a conductive material into which copper is less likely to diffuse is provided between the semiconductor layer and a wiring or an electrode that contains copper, the reliability of the transistor 100 can be increased.

Examples of a conductive material into which copper is less likely to diffuse include a metal material having a higher melting point than copper (e.g., tungsten, titanium, and tantalum) and a nitride material thereof. Moreover, a wiring or an electrode containing copper may be covered with such a conductive material. When a wiring or an electrode containing copper is covered with or wrapped by a conductive material into which copper is less likely to diffuse, the reliability of the transistor 100 can be further increased.

When a conductive material that has a function of absorbing hydrogen when being subjected to heat treatment is used for regions of the electrodes 107a and 107b in contact with the semiconductor layer 106, the hydrogen concentration of the semiconductor layer 106 can be reduced by heat treatment performed later. Examples of a conductive material with a function of absorbing hydrogen include titanium, indium zinc oxide, and indium tin oxide containing silicon oxide.

### [Semiconductor Layer]

The semiconductor layer 106 can be formed using an amorphous semiconductor, a microcrystalline semiconductor, a polycrystalline semiconductor, or the like. For example, amorphous silicon or microcrystalline germanium can be used. Alternatively, a compound semiconductor such as silicon carbide, gallium arsenide, a metal oxide, or a nitride semiconductor, an organic semiconductor, or the like can be used.

It is particularly preferable that an oxide semiconductor, which is one kind of metal oxide, be used for the semiconductor layer 106. The band gap of a metal oxide is greater than or equal to 2 eV; thus, when a metal oxide is used for the semiconductor layer 106, a transistor with an extremely low off-state current can be achieved. A transistor using a metal oxide in the semiconductor layer where the channel is formed (also referred to as an “OS transistor”) has high withstand voltage between its source and drain. Thus, a transistor with high reliability can be provided. Furthermore, a transistor with high output voltage and high withstand voltage can be provided. Furthermore, a semiconductor device or the like with high reliability can be provided. Furthermore, a semiconductor device with high output voltage and high withstand voltage can be provided.

The metal oxide preferably contains at least one of indium and zinc. In particular, indium and zinc are preferably contained. In addition, an element M (M is one or more of aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like) may be contained.

A metal oxide layer with low carrier density is preferably used as the semiconductor layer 106. In order to reduce the carrier density of the metal oxide layer, the impurity concentration in the metal oxide layer is reduced so that the density of defect states is reduced. In this specification and the like, a state with a low impurity concentration and a low density of defect states is referred to as a highly purified intrinsic or substantially highly purified intrinsic state. For example, the metal oxide layer has a carrier density of lower than 8×10¹¹/cm³, preferably lower than 1×10¹¹/cm³, further preferably lower than 1×10¹⁰/cm³ and higher than or equal to 1×10⁻⁹/cm³.

The highly purified intrinsic or substantially highly purified intrinsic metal oxide layer has a low density of defect states and accordingly has a low density of trap states in some cases.

Charge trapped by the trap states in the metal oxide layer takes a long time to be released and may behave like fixed charge. Thus, the OS transistor including the metal oxide layer with a high density of trap states has unstable electrical characteristics in some cases.

Thus, in order to obtain stable electrical characteristics of the OS transistor, it is effective to reduce the impurity concentration in the metal oxide layer. In addition, in order to reduce the impurity concentration in the metal oxide layer, it is preferable to also reduce the impurity concentrations in layers which are in close contact with the metal oxide layer. Examples of the impurities include hydrogen, alkali metal, and alkaline earth metal.

When the metal oxide layer contains alkali metal or alkaline earth metal, defect states are formed and carriers are generated, in some cases. Thus, a transistor in which a metal oxide that contains alkali metal or alkaline earth metal is used for the semiconductor layer is likely to be normally on. Therefore, it is preferable to reduce the concentration of alkali metal or alkaline earth metal in the metal oxide layer. Specifically, the concentration of alkali metal or alkaline earth metal in the metal oxide layer, which is measured by SIMS, is lower than or equal to 1×10¹⁸ atoms/cm³, preferably lower than or equal to 2×10¹⁶ atoms/cm³.

Hydrogen contained in the metal oxide layer reacts with oxygen bonded to a metal atom to be water, and thus causes an oxygen vacancy, in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, the transistor in which a metal oxide layer that contains hydrogen is used as the semiconductor layer is likely to be normally-on. Accordingly, it is preferable that hydrogen in the metal oxide layer be reduced as much as possible. Specifically, the hydrogen concentration of the metal oxide layer measured by SIMS is set lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When a metal oxide layer with sufficiently reduced impurity concentration is used as a channel formation region in a transistor, the transistor can have stable electrical characteristics.

In the case where the semiconductor layer 106 is formed by a sputtering method, a target containing indium is preferably used in order to reduce the number of particles. In addition, when an oxide target having a high atomic ratio of the element M is used, the conductivity of the target may be decreased. Particularly in the case where a target containing indium is used, the conductivity of the target can be increased and DC discharge or AC discharge is facilitated; thus, deposition over a large substrate can be easily performed. Thus, semiconductor devices can be manufactured with improved productivity.

When the semiconductor layer 106 is formed by a sputtering method, the atomic ratio of a target can be set to In:Ga:Zn=1:1:0.5, 1:1:1, 1:1:1.2, 1:1:2, 1:3:2, 1:3:4, 1:4:4, 3:1:1, 3:1:2, 3:1:4, 4:2:4.1, 5:1:6, or 5:1:7, for example.

In the case where the semiconductor layer 106 is formed by a sputtering method, a film having an atomic ratio deviated from the atomic ratio of the target is formed in some cases. Especially for zinc, the atomic ratio of zinc in a deposited film is smaller than the atomic ratio of the target in some cases. Specifically, the film has an atomic ratio of zinc of 40 atomic % to 90 atomic % of the atomic ratio of zinc in the target in some cases.

For the semiconductor layer 106_1, a metal oxide with a wide energy gap is used, for example. The energy gap of the semiconductor layer 106_1 is, for example, greater than or equal to 2.5 eV and less than or equal to 4.2 eV, preferably greater than or equal to 2.8 eV and less than or equal to 3.8 eV, further preferably greater than or equal to 3 eV and less than or equal to 3.5 eV.

When the semiconductor layer 106 has a two-layer or three-layer structure as illustrated in FIGS. 1B and 1C or FIG. 2B, the semiconductor layer 106 may be a stack of metal oxides which differ in crystal structure, material composition, or the like. For example, CAC-OS may be used for the semiconductor layer 106_1, and CAAC-OS may be used for the semiconductor layer 106_2 and/or the semiconductor layer 106_3.

The semiconductor layer 106_2 is preferably formed using a material containing one or more kinds of metal elements contained in the semiconductor layer 106_1. Similarly, the semiconductor layer 106_3 is preferably formed using a material containing one or more kinds of metal elements contained in the semiconductor layer 106_1. With the use of such a material, interface states at interfaces between the semiconductor layer 106_3 and the semiconductor layer 106_1 and between the semiconductor layer 106_2 and the semiconductor layer 106_1 are less likely to be generated. Accordingly, carriers are not likely to be scattered or captured at the interfaces, which results in an improvement in field-effect mobility of the transistor. Furthermore, threshold-voltage variation of the transistor can be reduced. Thus, a semiconductor device having favorable electrical characteristics can be obtained.

When the semiconductor layer 106_1 is an In-M-Zn oxide (oxide containing In, the element M, and Zn) with an atomic ratio In:M:Zn of x₂:y₂:z₂ and each of the semiconductor layers 106_2 and 106_3 is an In-M-Zn oxide with an atomic ratio In:M:Zn of x₁:y₁:z₁, y₁/x₁ is preferably larger than y₂/x₂, further preferably greater than or equal to 1.5 times y₂/x₂, still further preferably greater than or equal to two times y₂/x₂, yet still further preferably greater than or equal to three times y₂/x₂. Here, in the semiconductor layer 106b, y₂ is preferably larger than or equal to x₂, in which case the transistor can have stable electrical characteristics. However, when y₂ is five or more times as large as x₂, the field-effect mobility of the transistor is reduced; accordingly, y₂ is preferably smaller than five times x₂. With the above structure, each of the semiconductor layers 106_2 and 106_3 can be a layer in which oxygen vacancy is less likely to be formed than in the semiconductor layer 106_1.

In the case where the semiconductor layer 106_3 is an In-M-Zn oxide and the total content of In and M is assumed to be 100 atomic %, the proportions of In and M are preferably less than 50 atomic % and greater than 50 atomic %, respectively, further preferably less than 25 atomic % and greater than 75 atomic %, respectively. In the case where the semiconductor layer 106_1 is an In-M-Zn oxide and the total content of In and M is assumed to be 100 atomic %, the proportions of In and M are preferably greater than 25 atomic % and less than 75 atomic %, respectively, further preferably greater than 34 atomic % and less than 66 atomic %, respectively. In the case where the semiconductor layer 106_2 is an In-M-Zn oxide and the total content of In and M is assumed to be 100 atomic %, the proportions of In and M are preferably less than 50 atomic % and greater than 50 atomic %, respectively, further preferably less than 25 atomic % and greater than 75 atomic %, respectively. Note that the semiconductor layers 106_2 and 106_3 may be formed using the same type of oxide.

For example, an In—Ga—Zn oxide formed using a target with an atomic ratio In:Ga:Zn of 1:3:2, 1:3:4, 1:3:6, 1:4:5, 1:6:4, or 1:9:6 or an In—Ga oxide formed using a target with an atomic ratio In:Ga of 1:9 or 7:93 can be used for each of the semiconductor layers 106_2 and 106_3 containing In or Ga. Moreover, an In—Ga—Zn oxide formed using a target with an atomic ratio In:Ga:Zn of 1:1:1 or 3:1:2 can be used for the semiconductor layer 106_1, for example. Note that the atomic ratio of each of the semiconductor layers 106_1 to 106_3 may vary within a margin of ±20% of the corresponding atomic ratio.

For the semiconductor layer 106_1, an oxide having a higher electron affinity than the semiconductor layers 106_2 and 106_3 is preferably used. For example, the semiconductor layer 106_1 may be an oxide having an electron affinity higher than that of each of the semiconductor layers 106_2 and 106_3 by 0.07 eV or higher and 1.3 eV or lower, preferably 0.1 eV or higher and 0.7 eV or lower, further preferably 0.15 eV or higher and 0.4 eV or lower. Note that the electron affinity refers to an energy difference between the vacuum level and the conduction band minimum.

An indium gallium oxide has a small electron affinity and an excellent oxygen-blocking property. Therefore, the semiconductor layer 106_2 preferably contains indium gallium oxide. The gallium atomic ratio [Ga/(In+Ga)] is, for example, higher than or equal to 70%, preferably higher than or equal to 80%, more preferably higher than or equal to 90%.

Note that the semiconductor layer 106_2 and/or the semiconductor layer 106_3 may be gallium oxide. For example, when gallium oxide is used for the semiconductor layer 106_3, a leakage current generated between the electrode 102 and the semiconductor layer 106 can be reduced. In other words, the off-state current of the transistor 100 can be reduced.

At this time, when a gate voltage is applied, a channel is formed in the semiconductor layer 106_1 having the highest electron affinity among the semiconductor layers 106_1 to 106_3.

In order to give stable electrical characteristics to the OS transistor, it is preferable that impurities and oxygen vacancies in the metal oxide layer used for the semiconductor layer be reduced to highly purify the metal oxide layer so that at least the semiconductor layer 106_1 can be regarded as an intrinsic or substantially intrinsic metal oxide layer. Furthermore, preferably at least the channel formation region of the semiconductor layer 106_1 is regarded as an intrinsic or substantially intrinsic semiconductor layer.

### [Deposition Method]

The insulating layers, the conductive layers for forming electrodes or wirings, the semiconductor layers, or the like can be formed by a sputtering method, a spin coating method, a chemical vapor deposition (CVD) method (such as a thermal CVD method, a metal organic chemical vapor deposition (MOCVD) method, a plasma-enhanced CVD (PECVD) method, a high-density plasma CVD method, a low-pressure CVD (LPCVD) method, or an atmospheric-pressure CVD (APCVD) method), an atomic layer deposition (ALD) method, a plasma assist atomic layer deposition (PAALD) method, a molecular beam epitaxy (MBE) method, a pulsed laser deposition (PLD) method, a dipping method, a spray coating method, a droplet discharging method (such as an inkjet method), or a printing method (such as screen printing or offset printing).

By using the PECVD method, a high-quality film can be formed at a relatively low temperature of higher than or equal to RT and lower than or equal to 400° C. By using a deposition method that does not use plasma for deposition, such as the MOCVD method, the ALD method, or the thermal CVD method, damage is not easily caused on a surface on which the film is deposited. For example, a wiring, an electrode, an element (e.g., transistor or capacitor), or the like included in a semiconductor device might be charged up by receiving charges from plasma. In that case, accumulated charges might break the wiring, electrode, element, or the like included in the semiconductor device. Such plasma damage is not caused in the case of using a deposition method without using plasma, and thus the yield of a semiconductor device can be increased. In addition, since plasma damage does not occur in the deposition, a film with few defects can be obtained.

Unlike in a deposition method in which particles ejected from a target or the like are deposited, in a CVD method and an ALD method, a film is formed by reaction at a surface of an object. Thus, a CVD method and an ALD method enable favorable step coverage almost regardless of the shape of an object. In particular, an ALD method enables excellent step coverage and excellent thickness uniformity and can be favorably used for covering a surface of an opening with a high aspect ratio, for example. On the other hand, an ALD method has a relatively low deposition rate; thus, it is sometimes preferable to combine an ALD method with another deposition method with a high deposition rate such as a CVD method.

When a CVD method or an ALD method is used, the composition of a film to be formed can be controlled with a flow rate ratio of the source gases. For example, by a CVD method or an ALD method, a film with a certain composition can be formed depending on a flow rate ratio of the source gases. Moreover, with a CVD method or an ALD method, by changing the flow rate ratio of the source gases while forming the film, a film whose composition is continuously changed can be formed. In the case where the film is formed while changing the flow rate ratio of the source gases, as compared to the case where the film is formed using a plurality of treatment chambers, time taken for the deposition can be reduced because time taken for transfer and pressure adjustment is omitted. Thus, semiconductor devices can be manufactured with improved productivity.

In the case where a film is formed by an ALD method, a gas that does not contain chlorine is preferably used as a material gas.

When the metal oxide is formed by a sputtering method, each treatment chamber of a sputtering apparatus is preferably evacuated to a high vacuum (to the degree of approximately 5×10⁻⁷ Pa to 1×10⁻⁴ Pa) by an adsorption vacuum pump such as a cryopump so that water and the like acting as impurities for the metal oxide are removed as much as possible. In particular, the partial pressure of gas molecules corresponding to H₂O (gas molecules corresponding to m/z=18) in the treatment chamber in the standby mode of the sputtering apparatus is preferably lower than or equal to 1×10⁻⁴ Pa, further preferably 5×10⁻⁵ Pa. The deposition temperature is preferably higher than or equal to RT and lower than or equal to 500° C., further preferably higher than or equal to RT and lower than or equal to 300° C., still preferably higher than or equal to RT and lower than or equal to 200° C.

In addition, increasing the purity of a sputtering gas is necessary. For example, when a gas which is highly purified to have a dew point of −40° C. or lower, preferably −80° C. or lower, further preferably −100° C. or lower, still further preferably −120° C. or lower, is used as a sputtering gas, i.e., the oxygen gas or the argon gas, entry of moisture or the like into the metal oxide layer can be minimized.

In the case where the insulating layers, the conductive layers, the semiconductor layers, or the like are formed by a sputtering method using a sputtering gas containing oxygen, oxygen can be supplied to a layer to be formed. As the amount of oxygen contained in the sputtering gas increases, the amount of oxygen supplied to the layer to be formed tends to increase.

### <Example of Method for Manufacturing Transistor 100>

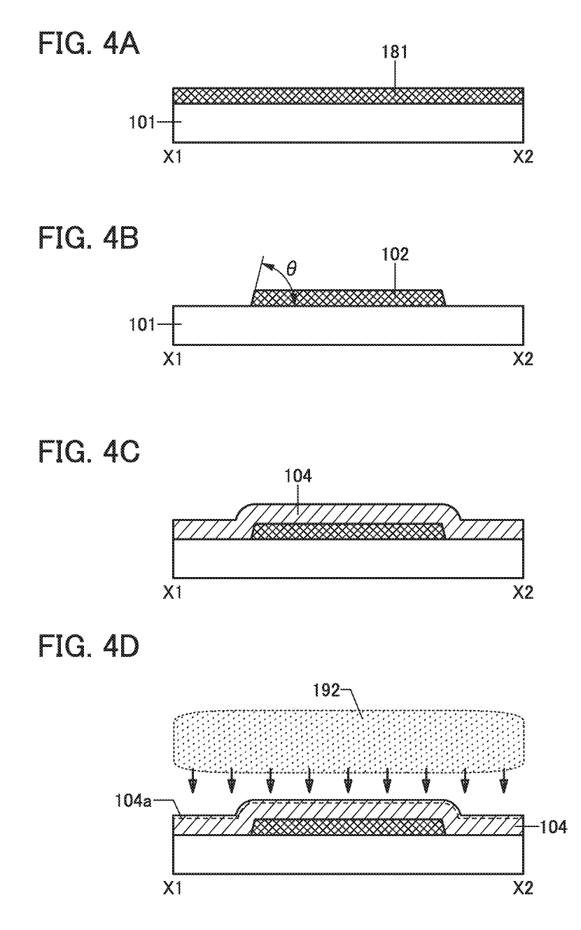

An example of a method for manufacturing the transistor 100 illustrated in FIGS. 1A to 1C is described with reference to FIGS. 4A to 4D, FIGS. 5A to 5D, FIGS. 6A to 6C, and FIGS. 7A and 7B. Cross-sectional views illustrated in FIGS. 4A to 4D, FIGS. 5A to 5D, FIGS. 6A to 6C, and FIGS. 7A and 7B each correspond to a cross section of a portion taken along a dashed dotted line X1-X2 in FIG. 1A.

[Step 1: Formation of Electrode 102] First, a conductive layer 181 for forming the electrode 102 is formed over the substrate 101 (see FIG. 4A). In this embodiment, aluminoborosilicate glass is used for the substrate 101. Furthermore, in this embodiment, a 100-nm-thick tungsten layer is formed as the conductive layer 181 by a sputtering method.

### [Step 2]

Next, a resist mask is formed (not illustrated). The resist mask can be formed by a photolithography method, a printing method, an inkjet method, or the like as appropriate. Formation of the resist mask by a printing method, an inkjet method, or the like needs no photomask; thus, manufacturing cost can be reduced.

The formation of the resist mask by a photolithography method can be performed in such a manner that a photosensitive resist is irradiated with light through a photomask and a portion of the resist which has been exposed to light (or has not been exposed to light) is removed using a developing solution. Examples of light with which the photosensitive resist is irradiated include KrF excimer laser light, ArF excimer laser light, extreme ultraviolet (EUV) light, and the like. Alternatively, a liquid immersion technique may be employed in which light exposure is performed with a portion between a substrate and a projection lens filled with liquid (e.g., water). An electron beam or an ion beam may be used instead of the above-mentioned light. Note that a photomask is not necessary in the case of using an electron beam or an ion beam.

With the use of the resist mask as a mask, part of the conductive layer 181 is selectively removed to form the electrode 102 (see FIG. 4B). The insulating layer 181 can be removed by a dry etching method, a wet etching method, or the like. Both a dry etching method and a wet etching method may be used.

The resist mask is removed after the portion of the conductive layer 181 is removed. A dry etching method such as ashing or a wet etching method using a dedicated stripper or the like can be used for removal of the resist mask. Both a dry etching method and a wet etching method may be used.

A side surface of the electrode 102 is preferably tapered in cross section. A taper angle θ of the side surface of the electrode 102 is preferably greater than or equal to 20° and less than 90°, further preferably greater than or equal to 30° and less than 80°, still further preferably greater than or equal to 40° and less than 70°. Note that the taper angle θ refers to an angle formed by a side surface and a bottom surface of a layer having a tapered shape when the layer is seen from the cross-sectional direction (i.e., the direction of the plane perpendicular to the substrate surface).

The tapered shape of the side surface of the electrode 102 can prevent disconnection of a layer formed over the electrode 102 and improve the coverage. Moreover, the tapered shape of the side surface of the electrode 102 can relieve electric field concentration at an upper edge portion of the electrode 102. Meanwhile, if the taper angle θ is too small, miniaturization of the transistor is sometimes difficult or variations in opening size, wiring width, or the like sometimes increase.

The side surface of the electrode 102 may have a step-like shape, in which case disconnection of a layer formed thereover can be prevented and the coverage can be improved. As well as the side surface of the electrode 102, an edge portion of any layer can have a tapered shape or a step-like shape, in which case disconnection of a layer covering the layer (disconnection caused by a step) can be prevented, resulting in favorable coverage.

### [Step 3: Formation of Insulating Layer 104]

Next, the insulating layer 104 is formed (see FIG. 4C). In this embodiment, the insulating layer 104 has a three-layer structure of a first silicon nitride layer, a second silicon nitride layer, and a third silicon nitride layer. The three-layer structure can be formed as follows, for example.

For example, the first silicon nitride layer is formed to a thickness of 50 nm under the conditions where a silane gas at a flow rate of 200 sccm, a nitrogen gas at a flow rate of 2000 sccm, and an ammonia gas at a flow rate of 100 sccm are supplied as source gases to the treatment chamber of the PECVD apparatus, the pressure in the treatment chamber is controlled to 100 Pa, and a power of 2000 W is supplied using a 27.12 MHz high-frequency power source.

For example, the second silicon nitride layer is formed to a thickness of 300 nm under the conditions where a silane gas at a flow rate of 200 sccm, a nitrogen gas at a flow rate of 2000 sccm, and an ammonia gas at a flow rate of 2000 sccm are supplied as source gases to the treatment chamber of the PECVD apparatus, the pressure in the treatment chamber is controlled to 100 Pa, and a power of 2000 W is supplied using a 27.12 MHz high-frequency power source.

For example, the third silicon nitride layer is formed to a thickness of 50 nm under the conditions where a silane gas at a flow rate of 200 sccm, a nitrogen gas at a flow rate of 2000 sccm, and an ammonia gas at a flow rate of 100 sccm are supplied as source gases to the treatment chamber of the PECVD apparatus, the pressure in the treatment chamber is controlled to 100 Pa, and a power of 2000 W is supplied using a 27.12 MHz high-frequency power source.

Note that each of the first to third silicon nitride layers can be formed at a substrate temperature of higher than or equal to RT and lower than or equal to 350° C.

For example, when a conductive layer containing copper or the like is used as the electrode 102, the insulating layer 104 with the above three-layer structure provides the following effects.

The first silicon nitride layer can inhibit diffusion of copper elements from the electrode 102. The second silicon nitride layer has a function of releasing hydrogen and can improve the withstand voltage of an insulating layer functioning as a gate insulating layer. The third silicon nitride layer releases a small amount of hydrogen and can prevent diffusion of hydrogen released from the second silicon nitride layer.

### [Step 4: Oxygen Plasma Treatment]

After the insulating layer 104 is formed, the insulating layer 104 is exposed to a plasma atmosphere 192 containing oxygen without being exposed to the air during the step (see FIG. 4D). For example, supply of a material gas for forming the insulating layer 104 is stopped, and then plasma treatment is performed for approximately 10 seconds to 60 seconds under the conditions where an oxygen gas at a flow rate of 300 sccm is supplied to the treatment chamber, the pressure inside the treatment chamber is controlled to 40 Pa, and a power of 3000 W is supplied using a 27.12 MHz high-frequency power source.

Plasma treatment performed under an atmosphere containing a large amount of oxygen is also referred to as oxygen plasma treatment. Owing to oxygen ions, oxygen radicals, and/or the like, a surface of the insulating layer 104 is oxidized by being subjected to oxygen plasma treatment; as a result, the oxide layer 104a is formed. Thus, the oxide layer 104a can also be regarded as part of the insulating layer 104 substantially. The oxide layer 104a formed on the insulating layer 104 can reduce the hydrogen concentration of the surface of the insulating layer 104 to reduce the density of states of the surface of the insulating layer 104.

It is preferable that the oxide layer 104a be formed in the same treatment chamber as the insulating layer 104 subsequently to formation of the insulating layer 104, in which case the productivity of the transistor can be improved. Thus, the production cost of the transistor can be reduced.

An oxidation gas containing oxygen, e.g., oxygen, ozone, or nitrogen oxide, can be used as a gas for the oxygen plasma treatment. Oxygen or ozone is particularly preferred as the gas for the oxygen plasma treatment. Note that a rare gas may be added in the oxygen plasma treatment. The oxygen plasma treatment with the addition of a rare gas can reduce impurities such as hydrogen and carbon in the surface of the insulating layer 104 or the vicinity thereof. A gas containing oxygen and argon can be used in the oxygen plasma treatment, for example. When oxygen plasma treatment is performed in another treatment chamber after the oxide layer 104a is formed, it is preferable that a rare gas be also added in the oxygen plasma treatment. Particularly when oxygen plasma treatment is performed after the surface of the insulating layer 104 is exposed to the air unavoidably (or unintentionally), the oxygen plasma treatment is preferably performed with the addition of a rare gas.

The oxide layer 104a may be formed by heat treatment under an oxidization atmosphere instead of oxygen plasma treatment. Note that the oxide layer 104a is preferably formed by treatment under the conditions where a large amount of oxygen ions and/or a large amount of oxygen radicals are/is generated, e.g., oxygen plasma treatment.

### [Step 5: Formation of Semiconductor Layer 106]

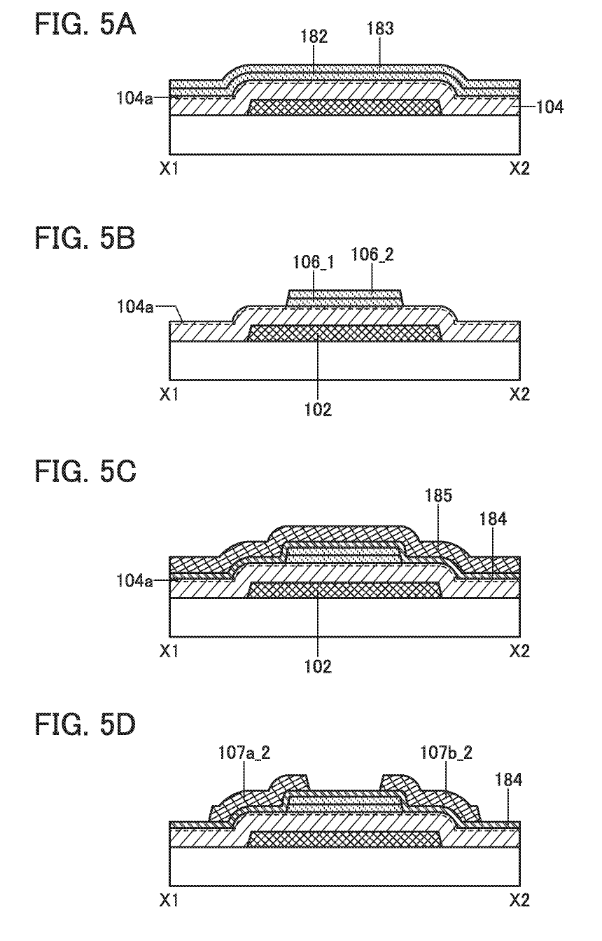

Next, a metal oxide layer 182 and a metal oxide layer 183 are formed in this order (see FIG. 5A). Note that oxygen plasma treatment may be performed before the metal oxide layer 182 is formed.

For the metal oxide layer 182, it is preferable to use indium zinc oxide, indium gallium zinc oxide formed using a target with an atomic ratio In:Ga:Zn=5:1:7 or 4:2:4.1, or the like.

In this embodiment, for the metal oxide layer 182, indium gallium zinc oxide is formed by a sputtering method using a target with an atomic ratio In:Ga:Zn=4:2:4.1. An oxygen gas or a mixed gas of oxygen and a rare gas is used as a sputtering gas. In this embodiment, a mixed gas of oxygen and argon at an oxygen flow rate percentage of 10% is used as the sputtering gas. The metal oxide layer is formed to a thickness of 20 nm under the conditions where the substrate temperature and the pressure in the treatment chamber are controlled to 130° C. and 0.6 Pa, respectively, and a power of 2500 W is supplied to the treatment chamber.

When the flow rate percentage of oxygen in the sputtering gas during deposition is higher than or equal to 0% and lower than or equal to 30%, preferably higher than or equal to 5% and lower than or equal to 20%, an oxygen-deficient metal oxide layer is formed. A transistor including an oxygen-deficient metal oxide layer as a semiconductor layer can have relatively high field-effect mobility.

For the metal oxide layer 183, it is preferable to use indium gallium zinc oxide formed using a target with an atomic ratio In:Ga:Zn=5:1:7, 4:2:4.1, or 1:1:1.2, for example.

Moreover, it is preferable to use a metal oxide layer with high crystallinity as the metal oxide layer 183. For example, a CAAC-OS is preferably used as the metal oxide layer 183. For example, in an etching step for forming the electrodes 107a and 107b, which is to be performed later, exposed part of the metal oxide layer might be etched to cause damage to the metal oxide layer. The metal oxide layer with high crystallinity is not likely to be etched in the etching step. When the metal oxide layer with high crystallinity is used as the metal oxide layer 183, damage to the metal oxide layer caused in the etching step can be reduced. Thus, the reliability of the transistor can be improved.

In this embodiment, a CAAC-OS is used as the metal oxide layer 183. Specifically, indium gallium zinc oxide is formed as the metal oxide layer 183 by a sputtering method using a target with an atomic ratio In:Ga:Zn=4:2:4.1. Oxygen or a mixed gas of oxygen and a rare gas is used as a sputtering gas. The flow rate percentage of oxygen in the sputtering gas for forming the metal oxide layer 183 is preferably higher than or equal to 70%, further preferably higher than or equal to 80%, still further preferably 100%. By increasing the proportion (flow rate percentage) of oxygen in the sputtering gas, the crystallinity of the metal oxide layer can be increased. In this embodiment, 100% oxygen is used as the sputtering gas. The metal oxide layer is formed to a thickness of 25 nm under the conditions where the substrate temperature and the pressure in the treatment chamber are controlled to 130° C. and 0.6 Pa, respectively, and a power of 2500 W is supplied to the treatment chamber.

In the formation of the metal oxide layer 182 and/or the metal oxide layer 183, part of oxygen in the sputtering gas is supplied to the layer under the metal oxide layers 182 and 183 in some cases. As the amount of oxygen contained in the sputtering gas increases, the amount of oxygen supplied to the layer under them tends to increase. Part of the supplied oxygen reacts with hydrogen left in the layer supplied with the oxygen to produce water, and the water is released by heat treatment performed later. Thus, the hydrogen concentration of the layer supplied with oxygen can be reduced. Moreover, when the amount of excess oxygen in the layer supplied with oxygen is increased, oxygen can be supplied to the metal oxide layer 182 (that is to be the semiconductor layer 106_1) by heat treatment performed later.

By introducing an impurity element after formation of the metal oxide layer 183, the threshold voltage of the transistor 100 can be changed. An impurity element can be introduced by an ion implantation method, an ion doping method, a plasma immersion ion implantation method, plasma treatment using a gas containing an impurity element, or the like.

After the metal oxide layer 183 is formed, heat treatment and/or oxygen doping treatment may be performed. The heat treatment and the oxygen doping treatment may be performed plural times.

The heat treatment is performed at a temperature of higher than or equal to 150° C. and lower than the strain point of the substrate, preferably higher than or equal to 200° C. and lower than or equal to 500° C., further preferably higher than or equal to 250° C. and lower than or equal to 400° C. The treatment time is shorter than or equal to 24 hours. Heat treatment for over 24 hours is not preferable because the productivity is reduced.

The heat treatment can be performed using an electric furnace, an RTA apparatus, or the like. With the use of an RTA apparatus, the heat treatment can be performed at a temperature higher than or equal to the strain point of the substrate if the heating time is short. Therefore, the heat treatment time can be shortened. The heat treatment may be performed under an atmosphere of nitrogen, oxygen, ultra-dry air (air in which water content is 20 ppm or less, preferably 1 ppm or less, more preferably 10 ppb or less), or a rare gas (e.g., argon or helium). The atmosphere of nitrogen, oxygen, ultra-dry air, or a rare gas preferably does not contain hydrogen, water, and the like.

Furthermore, after heat treatment is performed in a nitrogen atmosphere or a rare gas atmosphere, heat treatment may be additionally performed in an oxygen atmosphere or an ultra-dry air atmosphere. As a result, hydrogen, water, and the like can be released from the metal oxide layer, and oxygen can be supplied to the metal oxide layer at the same time. Consequently, oxygen vacancies in the metal oxide layer can be reduced.

### [Step 6]

A resist mask is formed by a photolithography method (not illustrated). With the use of the resist mask as a mask, part of the metal oxide layer 182 and part of the metal oxide layer 183 are selectively removed, so that the island-shaped metal oxide layers 106_1 and 106_2 are formed (see FIG. 5B).

After the semiconductor layers 106_1 and 106_2 are formed, heat treatment and/or oxygen doping treatment may be performed. Heat treatment and oxygen doping treatment may be performed repeatedly. In the case where the semiconductor layer 106 is formed to have a three-layer structure as illustrated in FIG. 2B, heat treatment and/or oxygen doping treatment may be performed after the semiconductor layers 106_1 to 106_3 are formed. Heat treatment and oxygen doping treatment may be performed repeatedly.

[Step 7: Formation of Electrodes 107a and 107b]

Next, a conductive layer 184 and a conductive layer 185 are formed in this order (see FIG. 5C). Since the conductive layer 184 is in contact with the semiconductor layer 106, the conductive layer 184 is preferably formed using a conductive material with a function of absorbing hydrogen through heat treatment. When the conductive layer 184 is formed using such a material, the hydrogen concentration of the semiconductor layer 106 can be reduced by heat treatment performed later. Examples of the conductive material with a function of absorbing hydrogen include titanium, indium zinc oxide, and indium tin oxide to which silicon is added.

In this embodiment, a 30-nm-thick titanium layer is formed as the conductive layer 184, and a 200-nm-thick copper layer is formed as the conductive layer 185 by a sputtering method.

### [Step 8]

A resist mask is formed by a photolithography method (not illustrated). With the use of the resist mask as a mask, part of the conductive layer 185 is selectively removed, so that the electrode 107a_2 and the electrode 107b_2 are formed (see FIG. 5D).

The conductive layer 185 can be removed by a dry etching method, a wet etching method, or the like. Both a dry etching method and a wet etching method may be used.

[Step 9]

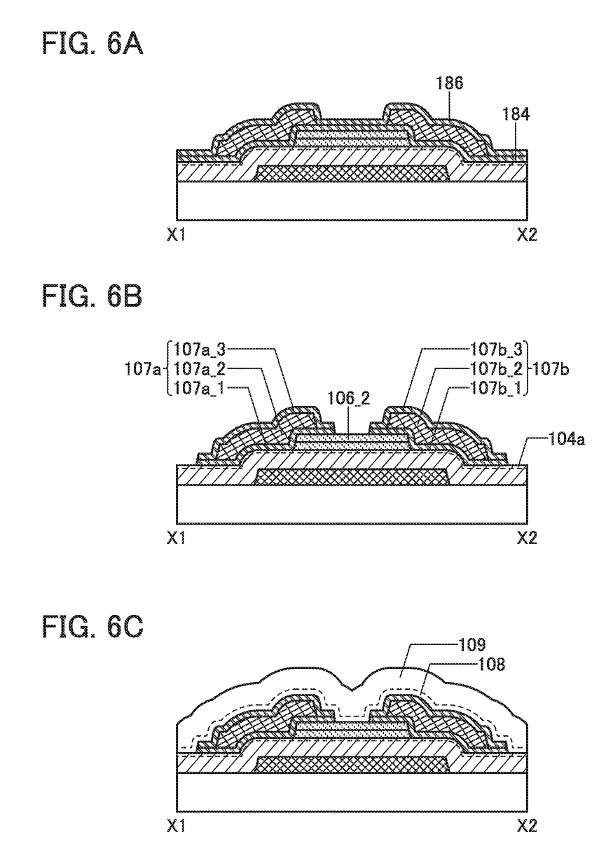

Next, a conductive layer 186 is formed (see FIG. 6A). In this embodiment, a 50-nm-thick titanium layer is formed as the conductive layer 186.

### [Step 10]

A resist mask is formed by a photolithography method (not illustrated). With the use of the resist mask as a mask, part of the conductive layer 184 and part of the conductive layer 186 are selectively removed, so that the electrodes 107a_1, 107a_3, 107b_1, and 107b_3 are formed (see FIG. 6B). In such a manner, the electrode 107a and the electrode 107b are formed.

The removal of the conductive layers 184 and 185 can be performed by a dry etching method, a wet etching method, or the like. Both a dry etching method and a wet etching method may be used.

In the case where part of the conductive layer 184 and part of the conductive layer 185 are removed by a dry etching method, an impurity element such as a residual component of an etching gas is sometimes attached to exposed portions of the semiconductor layer 106_2 and the insulating layer 104 (the oxide layer 104a). For example, when a chlorine-based gas is used as an etching gas, chlorine and the like are attached in some cases. Furthermore, when a hydrocarbon-based gas is used as an etching gas, carbon, hydrogen, and the like are attached in some cases.

The impurity element attached to the exposed surfaces of the semiconductor layer 106_2 and the insulating layer 104 (the oxide layer 104a) are preferably reduced. The impurity element can be reduced by cleaning treatment using acid such as hydrofluoric acid or phosphoric acid, cleaning treatment using ozone, cleaning treatment using ultraviolet rays, or the like. Plasma treatment using an oxidizing gas may be performed. For example, plasma treatment using a nitrous oxide gas may be performed. By the plasma treatment, the impurity element attached to the exposed surface can be reduced. Moreover, the plasma treatment is effective in removing an organic substance. Note that different types of cleaning treatment may be combined. Cleaning treatment and plasma treatment may be combined. In this embodiment, a 0.85% phosphoric acid solution is used in the cleaning treatment.

### [Step 11: Formation of Insulating Layers 108 and 109]

Next, the insulating layer 108 and the insulating layer 109 are formed in this order (see FIG. 6C). The insulating layer 108 and the insulating layer 109 are preferably formed successively without being exposed to the air.

The insulating layer 108 is preferably an insulating layer containing excess oxygen. The thickness of the insulating layer 108 is greater than or equal to 5 nm and less than or equal to 150 nm, preferably greater than or equal to 5 nm and less than or equal to 50 nm. When the insulating layer 108 is an insulating layer through which oxygen can pass, oxygen contained in the insulating layer 109 formed later can be transferred to the semiconductor layer 106.

For example, the insulating layer 108 can be a silicon oxynitride layer formed by a PECVD method. In that case, a deposition gas containing silicon and an oxidizing gas are preferably used as a source gas. Typical examples of a deposition gas containing silicon include a silane gas, a disilane gas, a trisilane gas, and a silane fluoride gas. Examples of an oxidizing gas include a dinitrogen monoxide gas and a nitrogen dioxide gas. The flow rate of the oxidation gas is more than or equal to 20 times and less than or equal to 5000 times, preferably more than or equal to 40 times and less than or equal to 100 times, that of the deposition gas.

In this embodiment, a 30-nm-thick silicon oxynitride layer is formed as the insulating layer 108. Specifically, the silicon oxynitride layer is formed by a PECVD method under the conditions where the substrate temperature is 220° C., a silane gas at a flow rate of 50 sccm and a dinitrogen monoxide gas at a flow rate of 2000 sccm are used as source gasses, the pressure in the treatment chamber is 20 Pa, and a high-frequency power of 100 W at 13.56 MHz is supplied to a parallel-plate electrode.

The insulating layer 109 is preferably an insulating layer containing excess oxygen. The thickness of the insulating layer 109 is greater than or equal to 30 nm and less than or equal to 500 nm, preferably greater than or equal to 50 nm and less than or equal to 400 nm.

The amount of defects in the insulating layer 109 is preferably small; as a typical example, the spin density corresponding to a signal that appears at g=2.001 due to a dangling bond of silicon is preferably lower than 1.5×10¹⁸ spins/cm³, further preferably lower than or equal to 1×10¹⁸ spins/cm³ by ESR measurement. Since the distance between the insulating layer 109 and the semiconductor layer 106 is larger than the distance between the insulating layer 108 and the semiconductor layer 106, the insulating layer 109 may have a higher defect density than the insulating layer 108.

The insulating layer 109 can be a silicon oxide layer or a silicon oxynitride layer formed by a PECVD method. For example, a silicon oxide layer or a silicon oxynitride layer is formed under the conditions where the substrate placed in the treatment chamber of the PECVD apparatus that is vacuum-evacuated is held at a temperature ranging from 180° C. to 400° C., the pressure in the treatment chamber into which source gasses are introduced ranges from 100 Pa to 250 Pa, preferably from 100 Pa to 200 Pa, and a high-frequency power of 0.17 W/cm² to 0.5 W/cm², preferably 0.25 W/cm² to 0.35 W/cm² is supplied to an electrode provided in the treatment chamber.

In formation of the insulating layer 109, when the high-frequency power with the above power density is supplied in the treatment chamber at the above pressure, decomposition efficiency of the source gases is increased in plasma. That is, oxygen radicals increase in the treatment chamber, and oxidation of the source gasses proceeds. As a result, the oxygen content of the insulating layer 109 is higher than that in the stoichiometric composition.

In the insulating layer formed at a substrate temperature within the above range, the bond between silicon and oxygen is weak, and accordingly, part of oxygen in the insulating layer is released by heat treatment in a later step. Thus, part of the released oxygen is supplied to the semiconductor layer 106.

In this embodiment, a 400-nm-thick silicon oxynitride layer is formed as the insulating layer 109. Specifically, the silicon oxynitride layer is formed by a PECVD method under the conditions where the substrate temperature is 220° C., a silane gas at a flow rate of 160 sccm and a dinitrogen monoxide gas at a flow rate of 4000 sccm are used as source gasses, the pressure in the treatment chamber is 200 Pa, and a high-frequency power of 1500 W at 13.56 MHz is supplied to the parallel-plate electrode.

Note that the insulating layer 108 functions as a protective layer for the semiconductor layer 106 in the step of forming the insulating layer 109. Consequently, the insulating layer 109 can be formed using the high-frequency power with a high power density while damage to the semiconductor layer 106 is reduced.

Note that in the formation conditions for the insulating layer 109, the flow rate of the deposition gas containing silicon relative to the oxidization gas can be increased, whereby the amount of defects in the insulating layer 109 can be reduced. Typically, it is possible to form an oxide insulating layer in which the number of defects is small, i.e., the spin density of a signal which appears at g=2.001 originating from a dangling bond of silicon is lower than 6×10¹⁷ spins/cm³, preferably lower than or equal to 3×10¹⁷ spins/cm³, or further preferably lower than or equal to 1.5×10¹⁷ spins/cm³, by ESR measurement. As a result, the reliability of the transistor can be improved.

### [Step 12]

Then, heat treatment is performed in an inert atmosphere to reduce impurities such as hydrogen and moisture included in the insulating layers 108 and 109. Note that the heat treatment may be performed under a reduced pressure without supply of an inert gas or the like. In this embodiment, the heat treatment is performed at 350° C. in a nitrogen atmosphere for one hour. Oxygen doping treatment may be performed following the heat treatment.

### [Step 13: Formation of Insulating Layer 110]

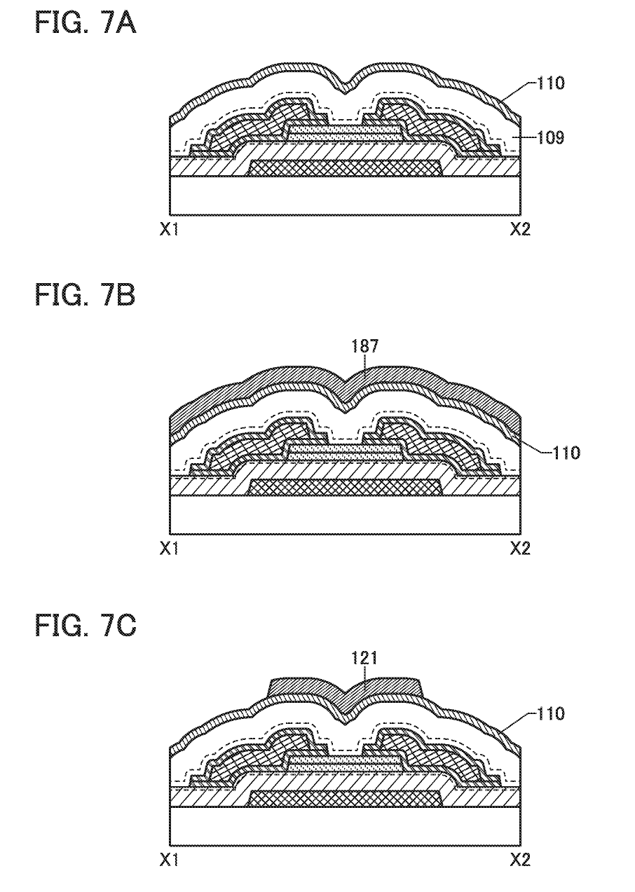

Next, the insulating layer 110 is formed (see FIG. 7A). As described above, the insulating layer 110 is preferably formed using an insulating material which is relatively impermeable to impurities. Moreover, the insulating layer 110 is preferably formed using an insulating material into which oxygen is less likely to diffuse. The thickness of the insulating layer 110 may be greater than or equal to 5 nm and less than or equal to 200 nm.

In this embodiment, a silicon nitride layer is formed as the insulating layer 110. For example, the silicon nitride layer may be formed to a thickness of 100 nm under the conditions where a silane gas at a flow rate of 50 sccm, a nitrogen gas at a flow rate of 5000 sccm, and an ammonia gas at a flow rate of 100 sccm are supplied as source gases to the treatment chamber of the PECVD apparatus, the pressure in the treatment chamber is controlled to 100 Pa, and a power of 1000 W is supplied using a 27.12 MHz high-frequency power source.

### [Step 14: Formation of Electrode 121]

Subsequently, a conductive layer 187 is formed (see FIG. 7B). In this embodiment, a 100-nm-thick indium tin oxide layer containing silicon oxide is formed as the conductive layer 187.

### [Step 15]

A resist mask is formed by a photolithography method (not illustrated). With the use of the resist mask as a mask, part of the conductive layer 187 is selectively removed, so that the electrode 121 is formed (see FIG. 7C).

The removal of the conductive layers 184 and 185 can be performed by a dry etching method, a wet etching method, or the like. Both a dry etching method and a wet etching method may be used.

After the electrode 121 is formed, heat treatment is performed at 250° C. in a nitrogen atmosphere for one hour.

### [Step 16: Formation of Insulating Layer 113]

The insulating layer 113 with a flat surface may be provided above the transistor 100 as illustrated in FIG. 3B. For example, an acrylic-based resin liquid is applied, and then baking is performed at 250° C. in a nitrogen atmosphere for one hour. Note that the baking temperature, the baking time, and the like vary according to a material used as the insulating layer 113. The thickness of the insulating layer 113 can be determined as appropriate as long as a flat surface is obtained. For example, a largest thickness of the insulating layer 113 may be approximately 0.5 μm to 3.0 μm.

A photosensitive resin material may be used as the insulating layer 113. When an opening or the like is formed in the insulating layer 113, the number of steps such as a step for forming a resist mask can be reduced by using a photosensitive resin material.

Heat treatment may be performed additionally after the formation of the insulating layer 113. For example, heat treatment may be performed at 250° C. in a nitrogen atmosphere for one hour.

### Modification Example

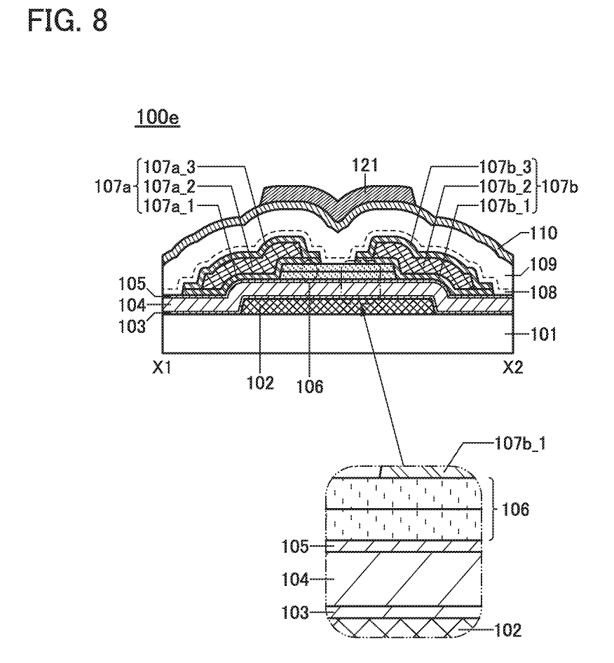

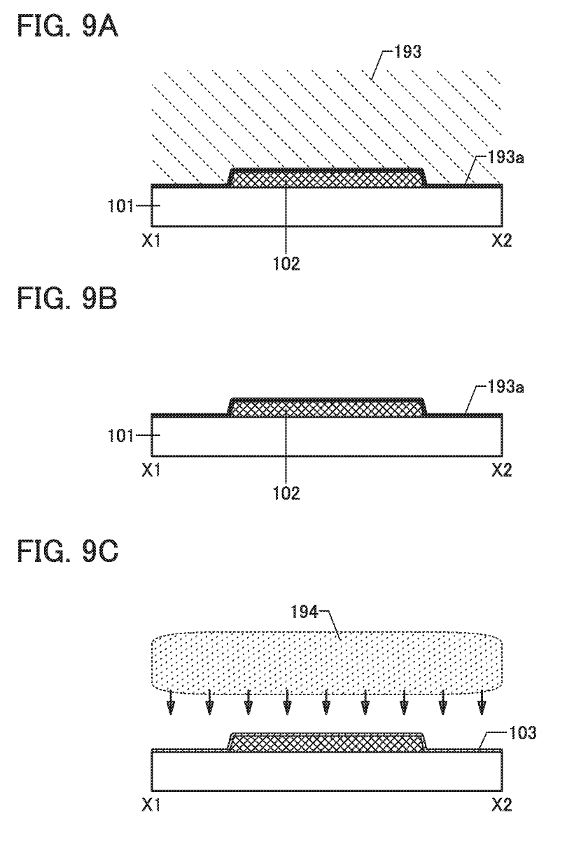

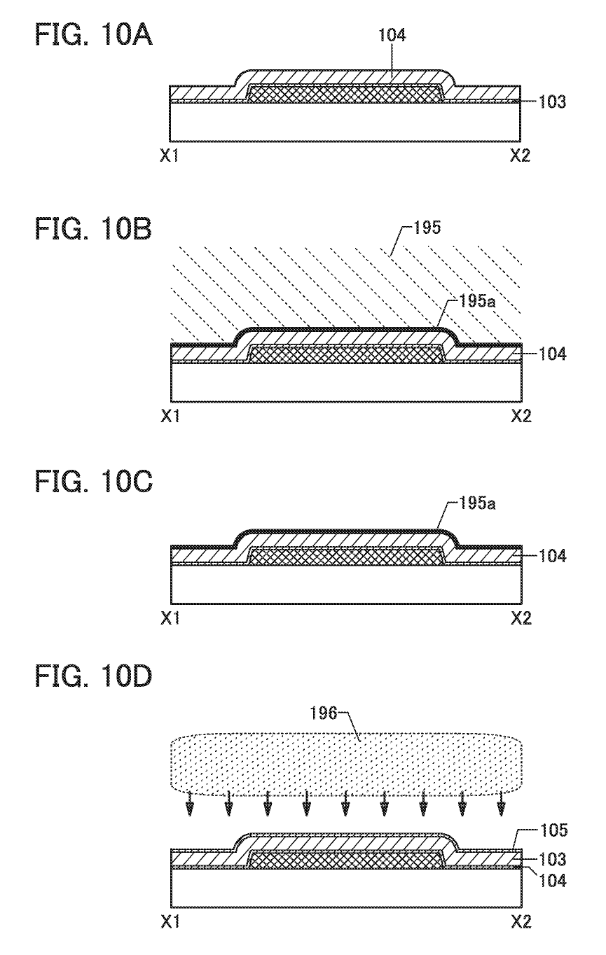

A transistor 100e which has a different structure from the transistor 100 is described with reference to FIG. 8, FIGS. 9A to 9C, and FIGS. 10A to 10D. FIG. 8, FIGS. 9A to 9C, and FIGS. 10A to 10D are cross-sectional views each corresponding to FIG. 1B. Note that differences from the transistor 100 are mainly described to avoid repeated description.

[Structure of Transistor 100e]

FIG. 8 is a cross-sectional view of the transistor 100e in a channel length direction. The transistor 100e differs from the transistor 100 in including an insulating layer 103 and an insulating layer 105. The insulating layer 103 is provided over the substrate 101 and the electrode 102, and the insulating layer 104 is provided over the insulating layer 103. The insulating layer 105 is provided over the insulating layer 104. The semiconductor layer 106 is provided over the insulating layer 105.

The insulating layers 103, 104, and 105 can function as gate insulating layers. The insulating layers 103 and 105 can each be formed using a material and a method similar to those for forming the insulating layers 104, 108, 109, and 110.

The insulating layers 103 and 105 are preferably formed using an insulating material which is relatively impermeable to impurities. For example, when a material including copper is used in the electrode 102, e.g., when the electrode 102 has a stacked-layer structure of titanium and copper, the insulating layer 103 is preferably formed using an insulating material that is relatively impermeable to metal elements such as copper. When a layer which includes a large amount of impurities such as hydrogen is provided below the insulating layer 105, the insulating layer 105 is preferably formed using an insulating material which is relatively impermeable to impurities such as hydrogen.

Particularly in the case where a material including copper is used in the electrode 102, when plasma damage or the like is caused in the electrode 102, impurities such as a copper element might diffuse from the electrode 102. Therefore, it is preferable that the insulating layer 103 be formed by a method which does not employ plasma or which is less likely to cause plasma damage. The insulating layer 103 is preferably formed by an ALD method or a PAALD method, for example. The thickness of the insulating layer 103 can be greater than or equal to 1 nm and less than or equal to 10 nm, preferably greater than or equal to 2 nm and less than 10 nm.

The thickness of the insulating layer 103 may be greater than or equal to 10 nm. Note that the deposition rates in an ALD method, a PAALD method, and the like are low; accordingly, an ALD method, a PAALD method, and the like do not contribute to improvement in the productivity. Therefore, after the insulating layer 103 is formed, the insulating layer 104 is formed by a PECVD method, which provides a high deposition rate. By such a method, the productivity of the transistor can be improved.

The electrode 102 is covered with the insulating layer 103 prior to formation of the insulating layer 104 by a PECVD method, whereby plasma damage is less likely to be caused in the electrode 102 in the formation of the insulating layer 104. When the electrode 102 is covered with the insulating layer 103, diffusion of a metal element from the electrode 102 can be prevented. The thickness of the insulating layer 104 may be greater than or equal to 100 nm and less than or equal to 800 nm, preferably greater than or equal to 200 nm and less than or equal to 500 nm.

It is preferable that the insulating layer 105 include oxygen. When an insulating layer includes oxygen, it is relatively easy to reduce the amount of hydrogen in the insulating layer and reduce the density of states in the surface of the insulating layer. The thickness of the insulating layer 105 can be greater than or equal to 1 nm and less than or equal to 10 nm, preferably greater than or equal to 2 nm and less than 10 nm. Note that the thickness of the insulating layer 105 may be greater than or equal to 10 nm.

[Example of Manufacturing Method of Transistor 100e]

Next, an example of a method for manufacturing the transistor 100e is described. First, steps up to Step 2 are performed in a similar manner to those in the method for manufacturing the transistor 100 that are described above.

### [Step A1: Formation of Insulating Layer 103]

Next, the insulating layer 103 is formed. In this embodiment, a silicon nitride layer is formed as the insulating layer 103 by a PAALD method.

First, the substrate 101 provided with the electrode 102 is introduced to a treatment chamber in which the pressure is reduced. After the introduction, the substrate temperature is held at higher than or equal to RT and lower than or equal to 450° C., preferably higher than or equal to 150° C. and lower than or equal to 450° C., further preferably higher than or equal to 200° C. and lower than or equal to 350° C. After that, a source gas 193 is supplied to the treatment chamber (see FIG. 9A). FIG. 9A illustrates a state where the source gas 193 is supplied to the treatment chamber to which the substrate 101 with the electrode 102 has been introduced.

A silane (SiH₄) gas, a disilane (Si₂H₆) gas, a trisilane (Si₃H₈) gas, or the like is used as the source gas 193. An inert gas (typically, argon, nitrogen, or the like) may be added to the source gas 193.

In this embodiment, a silane (SiH₄) gas at a flow rate of 100 sccm is supplied as the source gas 193 to the treatment chamber for five minutes at a substrate temperature of 220° C. The pressure in the treatment chamber is set to 40 Pa when the source gas 193 is supplied. By supplying the source gas 193 to the treatment chamber, part of the source gas 193 is deposited on surfaces of the electrode 102 and the substrate 101 to form a deposited layer 193a. In this embodiment, silane is deposited to form the deposited layer 193a.

Next, supply of the source gas 193 is stopped. Subsequently, the source gas 193 inside the treatment chamber is evaluated from the treatment chamber (see FIG. 9B).

Then, one or both of a nitrogen gas and an oxygen gas are supplied to the treatment chamber to generate a plasma atmosphere 194 containing one or both of nitrogen and oxygen (see FIG. 9C).

In this embodiment, a nitrogen gas is supplied to the treatment chamber to generate the plasma atmosphere 194 containing nitrogen. Plasma treatment performed under an atmosphere containing a large amount of nitrogen is also referred to as nitrogen plasma treatment. Nitrogen plasma treatment is performed, whereby the deposited layer 193a and nitrogen react to each other to form the insulating layer 103. In this embodiment, a silicon nitride layer is formed as the insulating layer 103.

When the plasma atmosphere 194 is generated by supplying a mixed gas of a nitrogen gas and an oxygen gas to the treatment chamber, a silicon oxynitride layer or a silicon nitride oxide layer is formed as the insulating layer 103.

### [Step A2: Formation of Insulating Layer 104]

Next, the insulating layer 104 is formed (see FIG. 10A). The insulating layer 104 can be formed by a step similar to Step 3 described above.

In this embodiment, at Step A2, a silicon nitride single layer is formed by a PECVD method. For example, the insulating layer 104 is formed to a thickness of 300 nm under the conditions where the substrate temperature is set to 350° C., a silane gas at a flow rate of 200 sccm, a nitrogen gas at a flow rate of 2000 sccm, and an ammonia gas at a flow rate of 2000 sccm are supplied as source gases to the treatment chamber of the PECVD apparatus, the pressure in the treatment chamber is controlled to 100 Pa, and a power of 2000 W is supplied using a 27.12 MHz high-frequency power source.

### [Step A3: Formation of Insulating Layer 105]

Then, the insulating layer 105 is formed. In this embodiment, a silicon oxide layer is formed as the insulating layer 105 by a PAALD method. Step A3 can be performed by a step similar to Step A1.

In this embodiment, a silane (SiH₄) gas at a flow rate of 100 sccm is supplied as a source gas 195 to the treatment chamber for five minutes at a substrate temperature of 220° C. The pressure in the treatment chamber is 40 Pa when the source gas 195 is supplied (see FIG. 10B). FIG. 10B illustrates a state where the source gas 195 is supplied to the treatment chamber to which the substrate 101 with the electrode 102 has been introduced.

By supplying the source gas 195 to the treatment chamber, part of the source gas 195 is deposited on a surface of the insulating layer 104, whereby a deposited layer 195a is formed. In this embodiment, silane is deposited to form the deposited layer 195a.

Next, supply of the source gas 195 is stopped. Subsequently, the source gas 195 is evaluated from the treatment chamber (see FIG. 10C).

Next, an oxygen gas is supplied to the treatment chamber to generate a plasma atmosphere 196 containing oxygen (see FIG. 10D). As described above, plasma treatment performed under an atmosphere containing a large amount of oxygen is also referred to as oxygen plasma treatment. Oxygen plasma treatment is performed, whereby the deposited layer 195a and oxygen react to each other to form the insulating layer 105. In this embodiment, a silicon oxide layer is formed as the insulating layer 105.

Note that Step A1 to Step A3 are preferably performed successively without exposure to the air during the steps. In addition, Step A1 to Step A3 are preferably performed in the same treatment chamber. When the insulating layers 103 to 105 are formed successively without being exposed to the air during the steps, a transistor with favorable electrical characteristics can be obtained. When the insulating layers 103 to 105 are formed successively in the same treatment chamber, the productivity of the transistor can be improved.

The subsequent steps are similar to Step 5 and the following steps that are described above. The insulating layer 105 may be formed using silicon nitride and then may be subjected to oxygen doping treatment or the like.

This embodiment can be implemented in appropriate combination with any of the structures described in the other embodiments and the like.

### Embodiment 2

In this embodiment, a display device is described as an example of a semiconductor device including any of the transistors disclosed in this specification and the like.

### <Display Device 1>

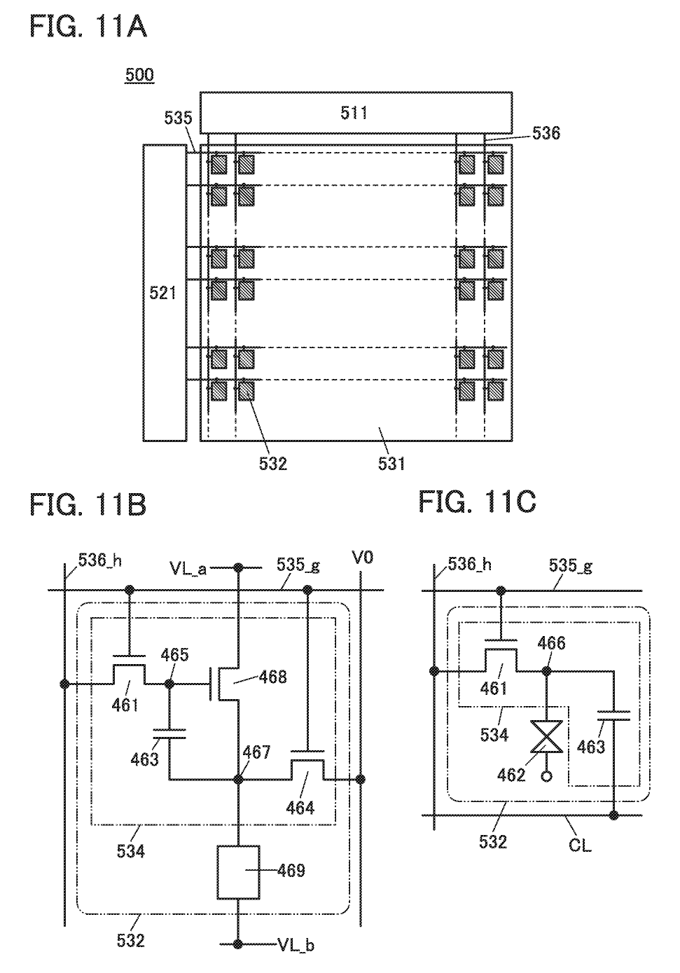

An example of a display device including any of the above transistors is described. FIG. 11A is a block diagram illustrating a configuration example of a display device 500.

The display device 500 in FIG. 11A includes a driver circuits 511, a driver circuit 521, and a display region 531. Note that the driver circuits 511 and 521 are collectively referred to as a driver circuit or a peripheral driver circuit in some cases.

The driver circuit 521 can function as a scan line driver circuit, for example. The driver circuit 511 can function as a signal line driver circuit, for example. Some sort of circuit may be provided to face the driver circuit 511 with the display region 531 positioned therebetween. Some sort of circuit may be provided to face the driver circuit 521 with the display region 531 positioned therebetween.

The display device 500 illustrated in FIG. 11A includes p wirings 535 that are arranged substantially parallel to each other and whose potentials are controlled by the driver circuit 521, and q wirings 536 that are arranged substantially parallel to each other and whose potentials are controlled by the driver circuit 511 (p and q are each a natural number of 1 or more). The display region 531 includes a plurality of pixels 532 arranged in a matrix. The pixel 532 includes a pixel circuit 534 and a display element.

When three pixels 532 function as one pixel, full-color display can be achieved. The three pixels 532 each control the transmittance, reflectance, amount of emitted light, or the like of red light, green light, or blue light. The light colors controlled by the three pixels 532 are not limited to the combination of red, green, and blue and may be yellow, cyan, and magenta.

A pixel 532 that controls white light may be added to the pixels controlling red light, green light, and blue light so that the four pixels 532 can collectively serve as one pixel. The addition of the pixel 532 controlling white light can increase the luminance of the display region. When the number of the pixels 532 functioning as one pixel is increased to use red, green, blue, yellow, cyan, and magenta in appropriate combination, the range of color reproduction can be widened.

Using the pixels arranged in a matrix of 1920×1080, the display device 500 can display an image with full high-definition (Full HD, also referred to as 2K resolution, 2K1K, 2K, or the like) quality. Using the pixels arranged in a matrix of 3840×2160, the display device 500 can display an image with Ultra HD (also referred to as 4K resolution, 4K2K, 4K, or the like) quality. Using the pixels arranged in a matrix of 7680×4320, the display device 500 can display an image with “Super Hi-Vision” (also referred to as 8K resolution, 8K4K, 8K, or the like) quality. Using a larger number of pixels, the display device 500 can display an image with 16K or 32K resolution.

A wiring 535_g in the gth row (g is a natural number of 1 top) is electrically connected to q pixels 532 in the gth row among the plurality of pixels 532 arranged in p rows and q columns in the display region 531. A wiring 536_h in the hth column (h is a natural number of 1 to q) is electrically connected top pixels 532 in the h-th column among the plurality of pixels 532 arranged in p rows and q columns.

### [Display Element]

The display device 500 can employ various modes and include various display elements. Examples of display elements include display elements containing a display medium whose contrast, luminance, reflectance, transmittance, or the like is changed by electrical or magnetic effect, such as an electroluminescent (EL) element (e.g., an EL element containing organic and inorganic materials, and an EL element containing an organic or inorganic material), an LED (e.g., a white LED, a red LED, a green LED, and a blue LED), a transistor (a transistor that emits light depending on current), an electron emitter, a liquid crystal element, electronic ink, an electrophoretic element, a grating light valve (GLV), a display element using microelectromechanical systems (MEMS), a digital micromirror device (DMD), a digital micro shutter (DMS), MIRASOL (registered trademark), an interferometric modulation (IMOD) element, a MEMS shutter display element, an optical-interference-type MEMS display element, an electrowetting element, a piezoelectric ceramic display, and a display element using a carbon nanotube. Moreover, quantum dots may be used for the display element.

Examples of display devices including EL elements include an EL display. Examples of display devices including electron emitters are a field emission display (FED) and an SED-type flat panel display (SED: surface-conduction electron-emitter display). Examples of display devices including quantum dots include a quantum dot display. Examples of display devices including liquid crystal elements include a liquid crystal display (e.g., a transmissive liquid crystal display, a transflective liquid crystal display, a reflective liquid crystal display, a direct-view liquid crystal display, and a projection liquid crystal display). Examples of display devices including electronic ink, electronic liquid powder (registered trademark), or electrophoretic elements include electronic paper. Other examples of display devices are a plasma display panel (PDP), a retina scanning type projector, and a display device including a micro LED.

In a transflective liquid crystal display and a reflective liquid crystal display, some or all of pixel electrodes function as reflective electrodes. For example, some or all of pixel electrodes are formed to contain aluminum, silver, or the like. In such a case, a memory circuit such as SRAM can be provided under the reflective electrodes. Thus, power consumption can be further reduced.

In the case of using an LED, graphene or graphite may be provided under an electrode or a nitride semiconductor of the LED. Graphene or graphite may be a multilayer film in which a plurality of layers are stacked. Providing graphene or graphite in the above manner facilitates formation of a nitride semiconductor thereover, such as an n-type GaN semiconductor layer including crystals. Furthermore, a p-type GaN semiconductor layer including crystals or the like can be provided thereover, and thus the LED can be formed. Note that an AlN layer may be provided between the n-type GaN semiconductor layer including crystals and graphene or graphite. The GaN semiconductor layers included in the LED may be formed by MOCVD. Note that when graphene is provided, the GaN semiconductor layers included in the LED can also be formed by a sputtering method.

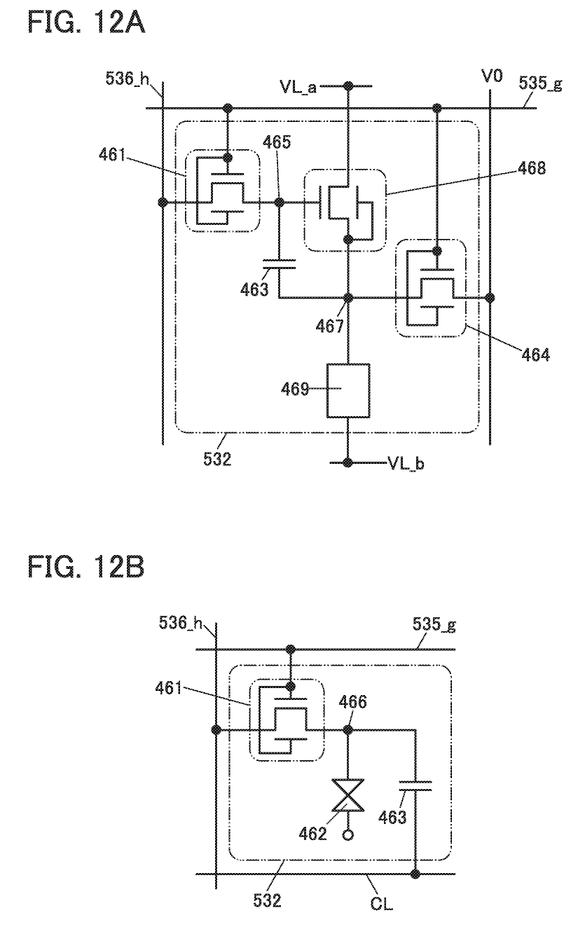

FIGS. 11B and 11C and FIGS. 12A and 12B illustrate circuit configuration examples that can be used for the pixel 532.

### [Example of Pixel Circuit for Light-Emitting Display Device]

The pixel circuit 534 shown in FIG. 11B includes a transistor 461, a capacitor 463, a transistor 468, and a transistor 464. The pixel circuit 534 in FIG. 11B is electrically connected to a light-emitting element 469 that can function as a display element.

The transistors 461, 468, and 464 can be OS transistors. It is particularly preferable to use an OS transistor as the transistor 461.

One of a source and a drain of the transistor 461 is electrically connected to the wiring 536_h. A gate of the transistor 461 is electrically connected to the wiring 535_g. The wiring 536_h supplies a video signal.

The transistor 461 has a function of controlling writing of a video signal to a node 465.

One of a pair of electrodes of the capacitor 463 is electrically connected to the node 465, and the other is electrically connected to a node 467. The other of the source and the drain of the transistor 461 is electrically connected to the node 465.

The capacitor 463 functions as a storage capacitor for storing data written to the node 465.

One of a source and a drain of the transistor 468 is electrically connected to a potential supply line VL_a, and the other is electrically connected to the node 467. A gate of the transistor 468 is electrically connected to the node 465.

One of a source and a drain of the transistor 464 is electrically connected to a potential supply line VO, and the other is electrically connected to the node 467. A gate of the transistor 464 is electrically connected to the wiring 535_g.

One of an anode and a cathode of the light-emitting element 469 is electrically connected to a potential supply line VL_b, and the other is electrically connected to the node 467.

As the light-emitting element 469, an organic electroluminescent element (organic EL element) can be used, for example. Note that the light-emitting element 469 is not limited thereto and may be an inorganic EL element containing an inorganic material, for example.

A high power supply potential VDD is supplied to one of the potential supply line VL_a and the potential supply line VL_b, and a low power supply potential VSS is supplied to the other, for example.

In the display device 500 including the pixel circuits 534 in FIG. 11B, the pixels 532 are sequentially selected row by row by the driver circuit 521, so that the transistors 461 and 464 are turned on and a video signal is written to the node 465.

The pixel 532 in which the data has been written to the node 465 is brought into a holding state when the transistors 461 and 464 are turned off. The amount of current flowing between the source and the drain of the transistor 468 is controlled in accordance with the potential of the data written to the node 465. The light-emitting element 469 emits light with a luminance corresponding to the amount of flowing current. This operation is sequentially performed row by row; thus, an image can be displayed.

As shown in FIG. 12A, each of the transistors 461, 464, and 468 may be a transistor with a back gate. In each of the transistors 461 and 464 in FIG. 12A, the gate is electrically connected to the back gate; thus, the gate and the back gate always have the same potential. The back gate of the transistor 468 is electrically connected to the node 467; thus, the back gate always has the same potential as the node 467.

Any of the above-described transistor can be used as at least one of the transistors 461, 468, and 464.

### [Example of Pixel Circuit for Liquid Crystal Display Device]

The pixel circuit 534 illustrated in FIG. 11C includes the transistor 461 and the capacitor 463. The pixel circuit 534 in FIG. 11C is electrically connected to a liquid crystal element 462 that can function as a display element. It is particularly preferable to use an OS transistor as the transistor 461.

The potential of one of a pair of electrodes of the liquid crystal element 462 is set as appropriate according to the specifications of the pixel circuit 534. For example, one of the pair of electrodes of the liquid crystal element 462 may be supplied with a common potential, or may have the same potential as a capacitor line CL which is described later. Alternatively, a potential supplied to one of the pair of electrodes of the liquid crystal element 462 may be different among the pixels 532. The other of the pair of electrodes of the liquid crystal element 462 is electrically connected to a node 466. The alignment state of the liquid crystal element 462 depends on data written to the node 466.

Examples of a method for driving the display device including the liquid crystal element 462 include a twisted nematic (TN) mode, a super-twisted nematic (STN) mode, a VA mode, an axially symmetric aligned micro-cell (ASM) mode, an optically compensated birefringence (OCB) mode, a ferroelectric liquid crystal (FLC) mode, an antiferroelectric liquid crystal (AFLC) mode, an MVA mode, a patterned vertical alignment (PVA) mode, an IPS mode, an FFS mode, and a transverse bend alignment (TBA) mode. Other examples of the method for driving the display device include an electrically controlled birefringence (ECB) mode, a polymer-dispersed liquid crystal (PDLC) mode, a polymer network liquid crystal (PNLC) mode, and a guest-host mode. Note that one embodiment of the present invention is not limited thereto, and various liquid crystal elements and driving methods can be employed.

When a liquid crystal element is used as the display element, thermotropic liquid crystal, low-molecular liquid crystal, high-molecular liquid crystal, polymer dispersed liquid crystal, ferroelectric liquid crystal, anti-ferroelectric liquid crystal, or the like can be used. Such a liquid crystal material exhibits a cholesteric phase, a smectic phase, a cubic phase, a chiral nematic phase, an isotropic phase, or the like depending on conditions.

Alternatively, liquid crystal exhibiting a blue phase for which an alignment film is not involved may be used. A blue phase is a liquid crystal phase that is generated just before a cholesteric phase changes into an isotropic phase while temperature of cholesteric liquid crystal is increased. Since the blue phase is only generated within a narrow range of temperatures, a liquid crystal composition containing a chiral material at 5 wt % or more is used for the liquid crystal layer in order to improve the temperature range. The liquid crystal composition that includes the liquid crystal exhibiting a blue phase and a chiral material has a short response time of 1 msec or less and has optical isotropy, which makes the alignment process unnecessary and the viewing angle dependence small. An alignment film does not need to be provided and rubbing treatment is thus not necessary; accordingly, electrostatic discharge damage caused by the rubbing treatment can be prevented and defects and damage of the liquid crystal display device in the manufacturing process can be reduced. Thus, productivity of the liquid crystal display device can be increased.

It is also possible to use a method called domain multiplication or multi-domain design, in which a pixel is divided into several regions (subpixels) and molecules are aligned in different directions in their respective regions.

The specific resistance of the liquid crystal material is higher than or equal to 1×10⁹ Ω·cm, preferably higher than or equal to 1×10¹¹ Ω·cm, further preferably higher than or equal to 1×10¹² Ω·cm. Note that the specific resistance in this specification is measured at 20° C.

In the pixel circuit 534 in the gth row and the hth column, one of the source and the drain of the transistor 461 is electrically connected to the wiring 536_h, and the other is electrically connected to the node 466. The gate of the transistor 461 is electrically connected to the wiring 535_g. The wiring 536_h supplies a video signal. The transistor 461 has a function of controlling writing of a video signal to the node 466.

One of a pair of electrodes of the capacitor 463 is electrically connected to a wiring to which a specific potential is supplied (hereinafter referred to as capacitor line CL), and the other is electrically connected to the node 466. The potential of the capacitor line CL is set as appropriate in accordance with the specifications of the pixel circuit 534. The capacitor 463 has a function as a storage capacitor for storing data written to the node 466.

For example, in the display device 500 including the pixel circuits 534 in FIG. 11C, the pixel circuits 534 are sequentially selected row by row by the driver circuit 521, so that the transistor 461 is turned on and a video signal is written to the node 466.

The pixel circuit 534 in which the video signal has been written to the node 466 is brought into a holding state when the transistor 461 is turned off. This operation is sequentially performed row by row; thus, an image can be displayed on the display region 531.

As shown in FIG. 12B, the transistor 461 may be a transistor with a back gate. In the transistor 461 in FIG. 12B, the gate is electrically connected to the back gate; thus, the gate and the back gate always have the same potential.

### [Structure Examples of Peripheral Circuits]

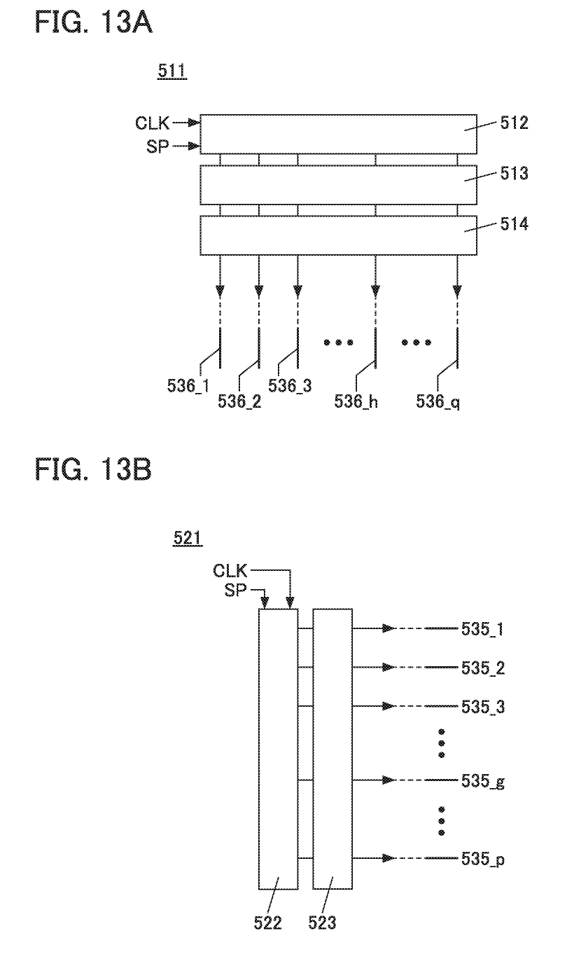

FIG. 13A illustrates a structure example of the driver circuit 511. The driver circuit 511 includes a shift register 512, a latch circuit 513, and a buffer 514. FIG. 13B illustrates a structure example of the driver circuit 521. The driver circuit 521 includes a shift register 522 and a buffer 523.

A start pulse SP, a clock signal CLK, and the like are input to the shift register 512 and the shift register 522.

### [Structure Example of Display Device]

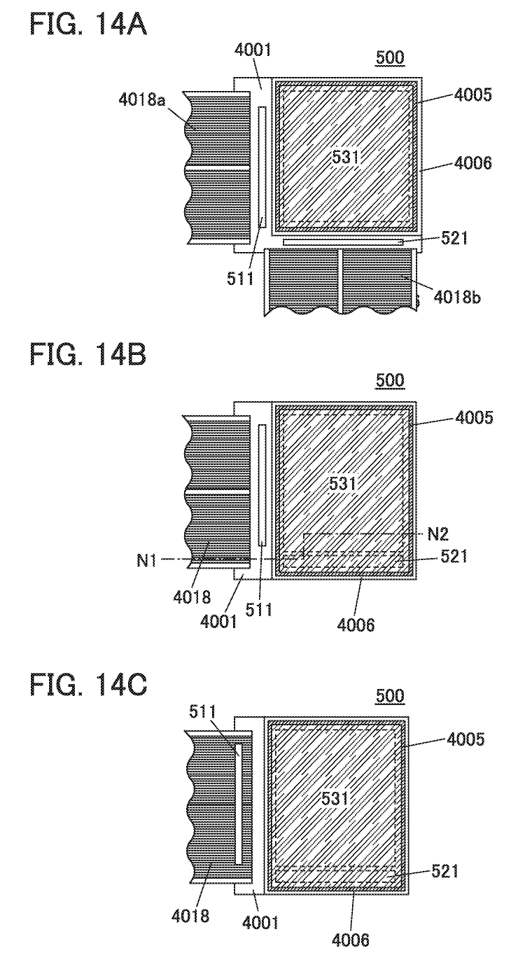

With the use of any of the transistors described in the above embodiments, some or all of driver circuits that include shift registers can be formed over a substrate where a pixel portion is formed, whereby a system-on-panel can be obtained. FIGS. 14A to 14C each illustrate a top view of the display device 500 to which a flexible printed circuit (FPC) is connected.

First, structure examples of the display device 500 including a liquid crystal element and the display device 500 including an EL element are described. In FIG. 14A, a sealant 4005 is provided so as to surround a display region 531 provided over a first substrate 4001, and the display region 531 is sealed by the sealant 4005 and a second substrate 4006. In FIG. 14A, a driver circuit 511 and a driver circuit 521 are formed using a single crystal semiconductor or a polycrystalline semiconductor over another substrate, and mounted in a region different from the region surrounded by the sealant 4005 over the first substrate 4001. Various signals and potentials are supplied to the driver circuit 511, the driver circuit 521, and the display region 531 through FPCs 4018a and 4018b.

In FIGS. 14B and 14C, the sealant 4005 is provided so as to surround the display region 531 and the driver circuit 521 that are provided over the first substrate 4001. The second substrate 4006 is provided over the display region 531 and the driver circuit 521. Thus, the display region 531 and the driver circuit 521 are sealed together with a display element, by the first substrate 4001, the sealant 4005, and the second substrate 4006. In FIGS. 14B and 14C, the driver circuit 511 that is formed using a single crystal semiconductor or a polycrystalline semiconductor over another substrate is mounted in a region that is different from the region surrounded by the sealant 4005 over the first substrate 4001. In FIGS. 14B and 14C, various signals and potentials are supplied through an FPC 4018 to the driver circuit 511, the driver circuit 521, and the display region 531.

Although FIGS. 14B and 14C each illustrate the example in which the driver circuit 511 is formed separately and mounted on the first substrate 4001, one embodiment of the present invention is not limited to this structure. The driver circuit 521 may be separately formed and then mounted, or only part of the driver circuit 511 or part of the driver circuit 521 may be separately formed and then mounted.

There is no particular limitation on a method for connecting a separately formed driver circuit; wire bonding, a chip on glass (COG), a tape carrier package (TCP), a chip on film (COF), or the like can be used. FIG. 14A illustrates an example in which the driver circuit 511 and the driver circuit 521 are mounted by COG. FIG. 14B illustrates an example in which the driver circuit 511 is mounted by COG. FIG. 14C illustrates an example in which the driver circuit 511 is mounted by TCP.

In some cases, the display device 500 encompasses a panel in which a display element is sealed, and a module in which an IC or the like including a controller is mounted on the panel.

The display region 531 and the driver circuit 521 provided over the first substrate include a plurality of transistors, and any of the transistors described in the above embodiments can be used.

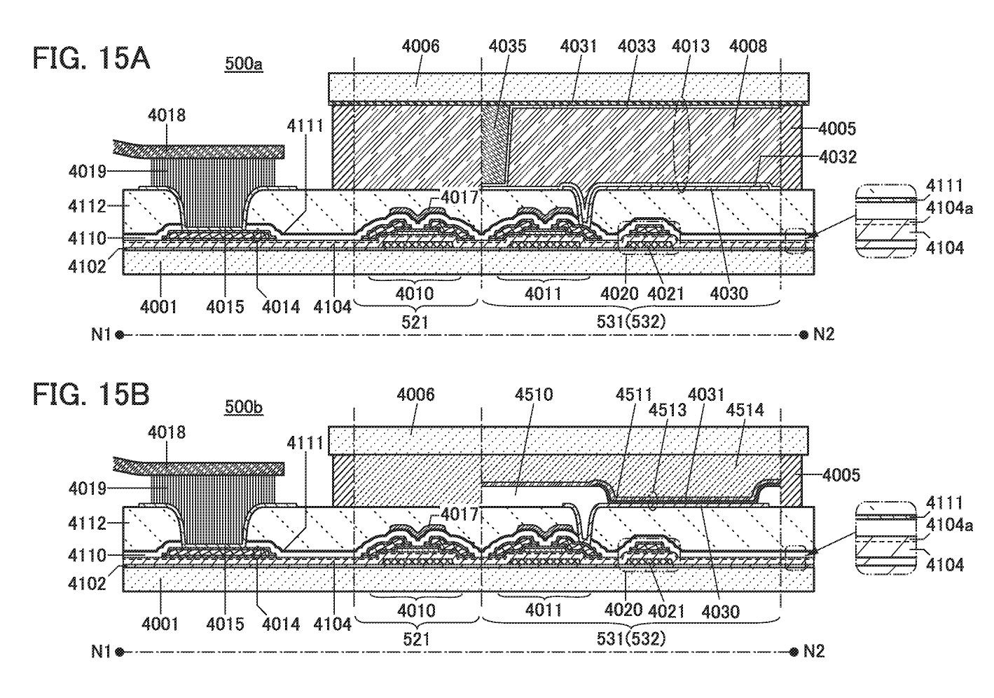

FIGS. 15A and 15B each illustrate a cross-sectional structure of a portion taken along a chain line N1-N2 in FIG. 14B. An example of a liquid crystal display device using a liquid crystal element as a display element is illustrated in FIG. 15A. An example of a light-emitting display device (also referred to as an EL display device) using a light-emitting element as a display element is illustrated in FIG. 15B. In this embodiment and the like, the display device 500 using a liquid crystal element as a display element is referred to as a display device 500a. In this embodiment and the like, the display device 500 using a light-emitting element as a display element is referred to as a display device 500b.

The display device 500a in FIG. 15A and the display device 500b in FIG. 15B each include an electrode 4015, and the electrode 4015 is electrically connected to a terminal included in the FPC 4018 via an anisotropic conductive layer 4019. The electrode 4015 is electrically connected to an electrode 4014 in an opening formed in insulating layers 4112, 4111, and 4110. Note that the insulating layer 4112 has a flat surface.

The electrode 4015 is formed using the same conductive layer as an electrode 4030, and the electrode 4014 is formed using the same conductive layer as source and drain electrodes of transistors 4010 and 4011.

The display region 531 and the driver circuit 521 provided over the first substrate 4001 each include a plurality of transistors. FIGS. 15A and 15B each illustrate an example where the transistor 4011 is included in the display region 531 and the transistor 4010 is included in the driver circuit 521. The insulating layer 4112 is provided over the transistors 4010 and 4011 in FIG. 15A. A partition 4510 is provided over the insulating layer 4112 in FIG. 15B.

The transistors 4010 and 4011 are provided over an insulating layer 4102. The transistors 4010 and 4011 each include an electrode 4017 formed over the insulating layer 4111. The insulating layer 4112 is formed over the electrode 4017. Note that the electrode 4017 can serve as a back gate electrode.

Any of the transistors described in the above embodiments can be used as the transistors 4010 and 4011. An OS transistor is preferably used as the transistors 4010 and 4011. The OS transistor, which is unlikely to be changed in electrical characteristics, is electrically stable; accordingly, the display devices of this embodiment illustrated in FIGS. 15A and 15B can be highly reliable.

In the OS transistor, the current in an off state (off-state current) can be low. Accordingly, an electrical signal such as an image signal can be held for a longer period, and a writing interval can be set longer in an on state. Thus, the frequency of refresh operation can be reduced, which leads to an effect of suppressing power consumption.

The OS transistor can have relatively high field-effect mobility and is thus capable of high-speed operation. Consequently, when the above transistor is used in a driver circuit portion or a pixel portion of a display device, high-quality images can be obtained. Moreover, the driver circuit portion and the pixel portion can be formed over one substrate with the use of OS transistors, so that the number of components of the display device can be reduced.

The display devices 500a and 500b each include a capacitor 4020. The capacitor 4020 includes an electrode 4021 formed in the same step as a gate electrode of the transistor 4011, and an electrode formed in the same step as a source electrode and a drain electrode of the transistor 4011. These electrodes overlap each other with insulating layers 4104 and 4104a positioned therebetween. The insulating layer 4104 may be formed in a manner similar to that of the insulating layer 104, for example. The insulating layer 4104a may be formed in a manner similar to that of the oxide layer 104a, for example.

In general, the capacitance of a capacitor provided in a pixel portion of a display device is set in consideration of leakage current or the like of a transistor provided in the pixel portion so that charges can be held for a predetermined period. The capacitance of the capacitor can be set in consideration of the off-state current of the transistor, or the like.

For example, when an OS transistor is used for a pixel of a liquid crystal display device, the capacitance of the capacitor can be one-third or smaller or one-fifth or smaller of the liquid crystal capacitance. Moreover, using an OS transistor can omit the formation of a capacitor.

The transistor 4011 included in the display region 531 is electrically connected to a display element. In FIG. 15A, a liquid crystal element 4013 that is the display element includes the electrode 4030, an electrode 4031, and a liquid crystal layer 4008. Alignment films 4032 and 4033 are provided so that the liquid crystal layer 4008 is positioned therebetween. The electrode 4031 is provided on the second substrate 4006 side, and the electrode 4030 and the electrode 4031 overlap each other with the liquid crystal layer 4008 positioned therebetween.

A spacer 4035 is a columnar spacer obtained by selective etching of an insulating layer and is provided in order to control a distance between the electrode 4030 and the electrode 4031 (a cell gap). Alternatively, a spherical spacer may be used.

In the display device 500, a black matrix (a light-blocking layer), an optical member (an optical substrate) such as a polarizing member, a retardation member, or an anti-reflection member, and the like may be provided as appropriate. For example, circular polarization may be employed by using a polarizing substrate and a retardation substrate. In addition, a backlight, a side light, or the like may be used as a light source.

The insulating layer 4111 can be formed in a manner similar to that of the insulating layer 110, for example.

As the display element included in the display device 500b, a light-emitting element utilizing electroluminescence (also referred to as an EL element) can be used. An EL element includes a layer containing a light-emitting compound (also referred to as EL layer) between a pair of electrodes. By generating a potential difference between the pair of electrodes that is greater than the threshold voltage of the EL element, holes are injected to the EL layer from the anode side and electrons are injected to the EL layer from the cathode side. The injected electrons and holes are recombined in the EL layer, and a light-emitting substance contained in the EL layer emits light.

EL elements are classified depending on whether a light-emitting material is an organic compound or an inorganic compound. In general, the former is referred to as an organic EL element, and the latter is referred to as an inorganic EL element.

In an organic EL element, by voltage application, electrons are injected from one electrode to the EL layer and holes are injected from the other electrode to the EL layer. Then, carriers (electrons and holes) are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

In addition to the light-emitting compound, the EL layer may also contain any of the following, for example: a substance with a high hole-injection property, a substance with a high hole-transport property, a hole-blocking material, a substance with a high electron-transport property, a substance with a high electron-injection property, and a substance with a bipolar property (a substance with a high electron- and hole-transport property).

The EL layer can be formed by an evaporation method (including a vacuum evaporation method), a transfer method, a printing method, an inkjet method, a coating method, or the like.

Inorganic EL elements are classified according to their element structures into a dispersion-type inorganic EL element and a thin-film inorganic EL element. A dispersion-type inorganic EL element includes a light-emitting layer where particles of a light-emitting material are dispersed in a binder, and its light emission mechanism is donor-acceptor recombination type light emission that utilizes a donor level and an acceptor level. A thin-film inorganic EL element has a structure where a light-emitting layer is sandwiched between dielectric layers, which are further sandwiched between electrodes, and its light emission mechanism is localization type light emission that utilizes inner-shell electron transition of metal ions. An example of using an organic EL element as a light-emitting element is described here.

In order to extract light emitted from the light-emitting element, at least one of a pair of electrodes needs to be transparent. The light-emitting element can have a top-emission structure in which emitted light is extracted from the side opposite to a substrate where a transistor and the light-emitting element are formed, a bottom-emission structure in which emitted light is extracted from the substrate side, or a dual-emission structure in which emitted light is extracted from both the substrate side and the side opposite to the substrate.

A light-emitting element 4513 serving as a display element is electrically connected to the transistor 4011 provided in the display region 531. The structure of the light-emitting element 4513 is a stacked-layer structure including the electrode 4030, a light-emitting layer 4511, and the electrode 4031; however, this embodiment is not limited to this structure. The structure of the light-emitting element 4513 can be changed as appropriate depending on a direction in which light is extracted from the light-emitting element 4513, for example.

The partition 4510 is formed using an organic insulating material or an inorganic insulating material. It is particularly preferred that the partition 4510 be formed using a photosensitive resin material to have an opening over the electrode 4030 so that a side surface of the opening slopes with continuous curvature.

The light-emitting layer 4511 may be formed using a single layer or a plurality of layers stacked.

A protective layer may be formed over the electrode 4031 and the partition 4510 in order to prevent entry of oxygen, hydrogen, moisture, carbon dioxide, or the like into the light-emitting element 4513. The protective layer can be formed using silicon nitride, silicon nitride oxide, aluminum oxide, aluminum nitride, aluminum oxynitride, aluminum nitride oxide, diamond like carbon (DLC), or the like. In a space that is formed with the first substrate 4001, the second substrate 4006, and the sealant 4005, a filler 4514 is provided for sealing. In this manner, the light-emitting element is preferably packaged (sealed) with a protective film (such as a laminate film or an ultraviolet curable resin film) or a cover member with high air-tightness and little degasification so that the light-emitting element is not exposed to the outside air.

As the filler 4514, an ultraviolet curable resin or a thermosetting resin can be used as well as an inert gas such as nitrogen or argon. For example, polyvinyl chloride (PVC), an acrylic-based resin, polyimide, an epoxy-based resin, a silicone-based resin, polyvinyl butyral (PVB), or ethylene vinyl acetate (EVA) can be used. A drying agent may be contained in the filler 4514.

For the sealant 4005, a glass material such as a glass frit, or a resin material such as a resin curable at room temperature (e.g., a two-component-mixture-type resin), a light curable resin, or a thermosetting resin can be used. A drying agent may be contained in the sealant 4005.

If necessary, an optical film such as a polarizing plate, a circularly polarizing plate (including an elliptically polarizing plate), a retardation plate (a quarter-wave plate or a half-wave plate), or a color filter may be provided as appropriate for a light-emitting surface of the light-emitting element. Furthermore, the polarizing plate or the circularly polarizing plate may be provided with an anti-reflection film. For example, it is possible to perform anti-glare treatment by which reflected light can be diffused by surface roughness to reduce glare.

When the light-emitting element has a microcavity structure, light with high color purity can be extracted. Furthermore, when a microcavity structure and a color filter are used in combination, glare can be reduced and visibility of a display image can be increased.

The electrode 4030 and the electrode 4031 (also called a pixel electrode layer, a common electrode layer, a counter electrode layer, or the like) for applying voltage to the display element may have light-transmitting properties or light-reflecting properties, which depends on the direction in which light is extracted, the position where the electrode is provided, and the pattern structure of the electrode.

The electrode 4030 and the electrode 4031 can be formed using a light-transmitting conductive material such as indium oxide containing tungsten oxide, indium zinc oxide containing tungsten oxide, indium oxide containing titanium oxide, indium tin oxide, indium tin oxide containing titanium oxide, indium zinc oxide, or indium tin oxide to which silicon oxide is added.

The electrode 4030 and the electrode 4031 can also be formed using one or more kinds selected from a metal such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), and silver (Ag); alloys thereof and nitrides thereof.

The electrode 4030 and the electrode 4031 can also be formed using a conductive composition containing a conductive high molecule (also referred to as conductive polymer). As a conductive high molecule, a so-called 7c-electron conjugated conductive polymer can be used. Examples include polyaniline or a derivative thereof, polypyrrole or a derivative thereof, polythiophene or a derivative thereof, a copolymer of two or more of aniline, pyrrole, and thiophene or a derivative thereof.

Since the transistor is easily broken owing to static electricity or the like, a protective circuit for protecting the driver circuit is preferably provided. The protective circuit is preferably formed using a nonlinear element.

With use of any of the transistors described in the above embodiments, a highly reliable display device can be provided. With the use of the transistor described in the above embodiment, a display device that has a high resolution, a large size, and high display quality can be provided. Furthermore, a display device with low power consumption can be provided.

### <Display Device 2>

Next, a configuration example of a display device 500c which includes both a reflective liquid crystal element and a light-emitting element as a display element 225 and can display an image both in a transmissive mode and in a reflective mode is described.

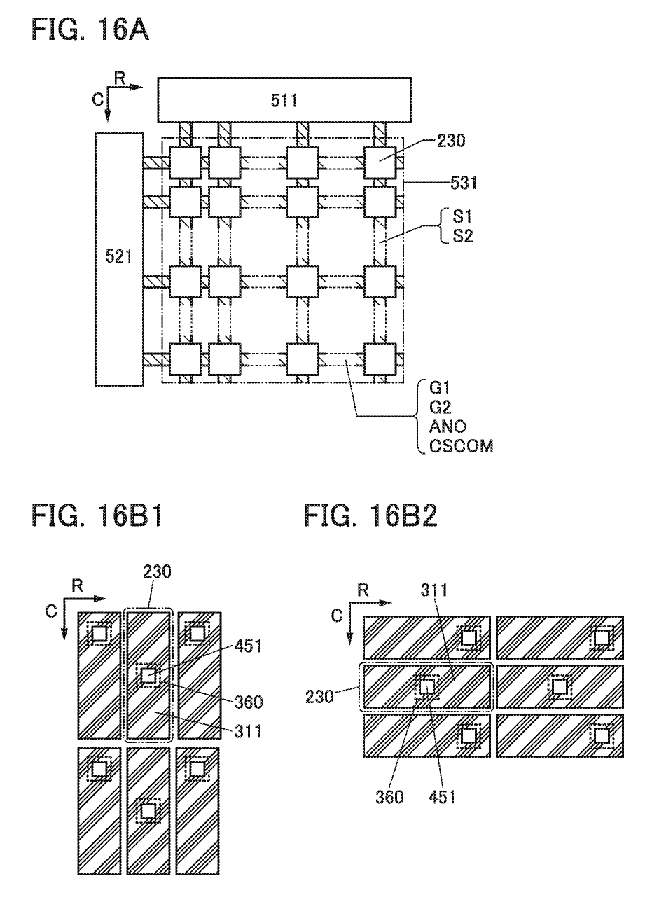

FIG. 16A is a block diagram illustrating a configuration example of the display region 531, the driver circuit 521, and the driver circuit 511. The display region 531 includes the plurality of pixels 230 arranged in a matrix, a plurality of wirings G1, a plurality of wirings G2, a plurality of wirings ANO, a plurality of wirings CSCOM, a plurality of wirings S1, and a plurality of wirings S2. The wirings G1, G2, ANO, and CSCOM are electrically connected to the plurality of pixels 230 arranged in a direction R and to the driver circuit 521. The wirings S1 and S2 are electrically connected to the plurality of pixels 230 arranged in a direction C and to the driver circuit 511.

Although FIG. 16A illustrates the configuration in which one driver circuit 521 and one driver circuit 511 are provided, the driver circuits 521 and 511 for driving the liquid crystal elements and the driver circuits 521 and 511 for driving the light-emitting elements may be provided separately.

The pixel 230 includes a reflective liquid crystal element and a light-emitting element. In the pixel 230, the liquid crystal element and the light-emitting element partly overlap each other.

FIG. 16B1 illustrates a structure example of an electrode 311 included in the pixel 230. The electrode 311 functions as a reflective electrode of the liquid crystal element in the pixel 230. The electrode 311 includes an opening 451.

In FIG. 16B1, a light-emitting element 360 in a region overlapping the electrode 311 is denoted by a dashed line. The light-emitting element 360 overlaps the opening 451 included in the electrode 311. Thus, light from the light-emitting element 360 is emitted to a display surface side through the opening 451.

In FIG. 16B1, the pixels 230 adjacent in the direction R correspond to different emission colors. As illustrated in FIG. 16B1, the openings 451 are preferably provided in different positions in the electrodes 311 so as not to be aligned in the two pixels adjacent to each other in the direction R. This allows the two light-emitting elements 360 to be apart from each other, thereby preventing light emitted from the light-emitting element 360 from entering a coloring layer in the adjacent pixel 230 (such a phenomenon is also referred to as crosstalk). Furthermore, since the two adjacent light-emitting elements 360 can be arranged apart from each other, a high-resolution display device is achieved even when EL layers of the light-emitting elements 360 are separately formed with a shadow mask or the like. Alternatively, arrangement illustrated in FIG. 16B2 may be employed.

If the ratio of the total area of the opening 451 to the total area except for the opening is too large, display performed using the liquid crystal element is dark. If the ratio of the total area of the opening 451 to the total area except for the opening is too small, display performed using the light-emitting element 360 is dark.

If the area of the opening 451 in the electrode 311 serving as a reflective electrode is too small, light emitted from the light-emitting element 360 is not efficiently extracted for display.

The shape of the opening 451 can be, for example, polygonal, quadrangular, elliptical, circular, or cross-shaped. Alternatively, the opening 451 may have a stripe shape, a slit shape, or a checkered pattern. The opening 451 may be close to the adjacent pixel. Preferably, the opening 451 is provided close to another pixel emitting light of the same color, in which case crosstalk can be suppressed.

### [Circuit Configuration Example]

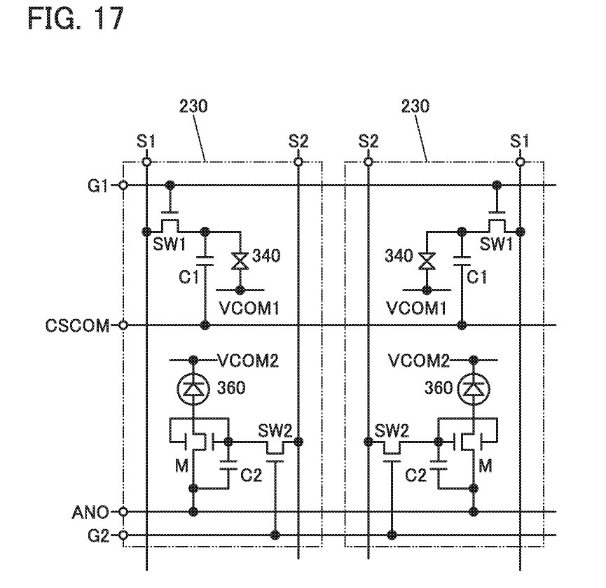

FIG. 17 is a circuit diagram illustrating a configuration example of the pixel 230. FIG. 17 shows two adjacent pixels 230.

The pixel 230 includes a switch SW1, a capacitor C1, a liquid crystal element 340, a switch SW2, a transistor M, a capacitor C2, the light-emitting element 360, and the like. The pixel 230 is electrically connected to the wiring G1, the wiring G2, the wiring ANO, the wiring CSCOM, the wiring S1, and the wiring S2. FIG. 17 also illustrates a wiring VCOM1 electrically connected to the liquid crystal element 340 and a wiring VCOM2 electrically connected to the light-emitting element 360.

FIG. 17 illustrates an example in which a transistor is used as each of the switches SW1 and SW2.

A gate of the switch SW1 is connected to the wiring G1. One of a source and a drain of the switch SW1 is connected to the wiring S1, and the other of the source and the drain is connected to one electrode of the capacitor C1 and one electrode of the liquid crystal element 340. The other electrode of the capacitor C1 is connected to the wiring CSCOM. The other electrode of the liquid crystal element 340 is connected to the wiring VCOM1.

A gate of the switch SW2 is connected to the wiring G2. One of a source and a drain of the switch SW2 is connected to the wiring S2, and the other of the source and the drain is connected to one electrode of the capacitor C2 and a gate of the transistor M. The other electrode of the capacitor C2 is connected to one of a source and a drain of the transistor M and the wiring ANO. The other of the source and the drain of the transistor M is connected to one electrode of the light-emitting element 360. The other electrode of the light-emitting element 360 is connected to the wiring VCOM2.

FIG. 17 illustrates an example in which the transistor M includes two gates between which a semiconductor is provided and which are connected to each other. This structure can increase the amount of current flowing through the transistor M.

The wiring G1 can be supplied with a signal for changing the on/off state of the switch SW1. A predetermined potential can be supplied to the wiring VCOM1. The wiring S1 can be supplied with a signal for changing the orientation of a liquid crystal of the liquid crystal element 340. A predetermined potential can be supplied to the wiring CSCOM.

The wiring G2 can be supplied with a signal for changing the on/off state of the switch SW2. The wiring VCOM2 and the wiring ANO can be supplied with potentials having a difference large enough to make the light-emitting element 360 emit light. The wiring S2 can be supplied with a signal for changing the conduction state of the transistor M.

In the pixel 230 of FIG. 17, for example, an image can be displayed in the reflective mode by driving the pixel with the signals supplied to the wiring G1 and the wiring Si and utilizing the optical modulation of the liquid crystal element 340. In the case where an image is displayed in the transmissive mode, the pixel is driven with the signals supplied to the wiring G2 and the wiring S2 and the light-emitting element 360 emits light. In the case where both modes are performed at the same time, the pixel can be driven with the signals supplied to the wiring G1, the wiring G2, the wiring S1, and the wiring S2.

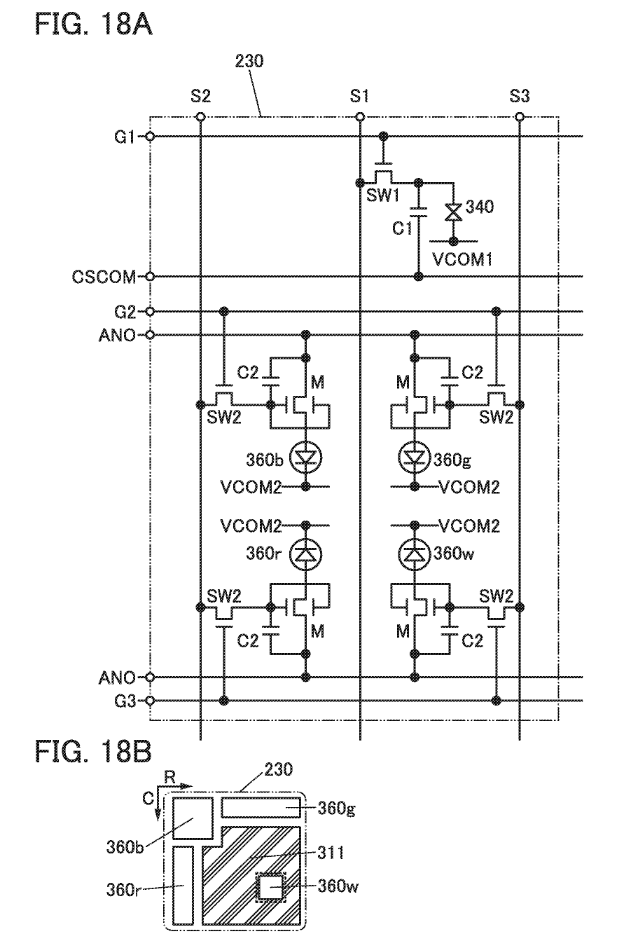

Although FIG. 17 illustrates the example in which one pixel 230 includes one liquid crystal element 340 and one light-emitting element 360, one embodiment of the present invention is not limited to this example. FIG. 18A illustrates an example in which one pixel 230 includes one liquid crystal element 340 and four light-emitting elements 360 (light-emitting elements 360r, 360g, 360b, and 360w). The pixel 230 illustrated in FIG. 18A differs from that in FIG. 17 in being capable of performing full-color display by one pixel.

In addition to the example in FIG. 17, the pixel 230 in FIG. 18A is connected to a wiring G3 and a wiring S3.

In the example illustrated in FIG. 18A, for example, light-emitting elements which exhibit red (R), green (G), blue (B), and white (W) can be used as the four light-emitting elements 360. A reflective liquid crystal element which exhibits white can be used as the liquid crystal element 340. This enables white display with high reflectance in the reflective mode. This also enables display with excellent color-rendering properties and low power consumption in the transmissive mode.

FIG. 18B illustrates a configuration example of the pixel 230. The pixel 230 includes the light-emitting element 360w which overlaps with the opening in the electrode 311 and the light-emitting elements 360r, 360g, and 360b which are located near the electrode 311. It is preferable that the light-emitting elements 360r, 360g, and 360b have substantially the same light-emitting area.

### [Cross-Sectional Structural Example]

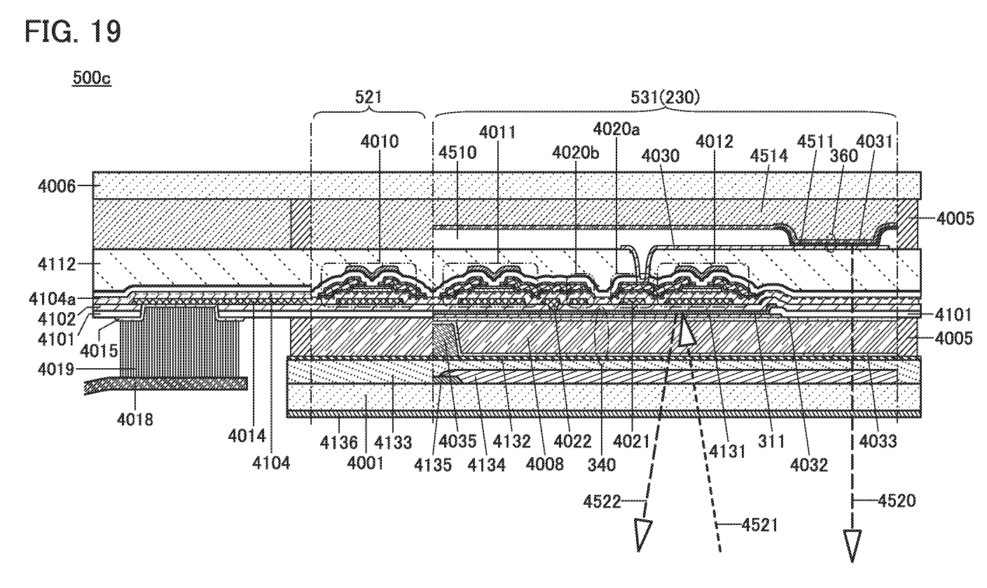

Next, a cross-sectional structural example of the display device 500c is described with reference to FIG. 19.

FIG. 19 illustrates the cross sections of the driver circuit 521, the display region 531, and the like. The driver circuit 521 includes a transistor 4010, and the display region 531 includes a transistor 4011 and a transistor 4012. The transistors 4010 to 4012 are provided over an insulating layer 4102.

The display device 500c illustrated in FIG. 19 includes a capacitor 4020a and a capacitor 4020b. The capacitor 4020a includes a region where part of the source electrode or part of the drain electrode of the transistor 4012 overlaps the electrode 4021 with the insulating layers 4104 and 4104a positioned therebetween. The capacitor 4020b has a structure similar to that of the capacitor 4020a. The transistor 4012 has a function of driving the light-emitting element 360, and the transistor 4011 has a function of driving the liquid crystal element 340.

The transistor 4012 is electrically connected to the light-emitting element 360. In this embodiment, an EL element is used as the light-emitting element 360.

When the light-emitting element 360 has a top emission structure, the electrode 4030 is formed using a conductive material having high light reflectivity. An example of such a material is a material containing A1, Ag, or the like. Stacked layers of a conductive material having high light reflectivity and a conductive material having a light-transmitting property may be used. In addition, the electrode 4031 is formed using a conductive material having a light-transmitting property.

When the light-emitting element 360 has a dual emission structure, the electrodes 4030 and 4031 are each formed using a conductive material having a light-transmitting property.

In this embodiment, the light-emitting element 360 has a bottom emission structure.

The display device 500c illustrated in FIG. 19 includes, below the insulating layer 4102, the electrode 311, an insulating layer 4101, an electrode 4131, the alignment film 4032, the liquid crystal layer 4008, the alignment film 4033, a spacer 4035, an electrode 4132, an overcoat layer 4133, a coloring layer 4134, the substrate 4001, a light-blocking layer 4135, and a polarizing plate 4136.

In the display device 500c illustrated in FIG. 19, the electrode 4015 is electrically connected to the electrode 4014 in an opening formed in the insulating layers 4101 and 4102. The electrode 4014 is formed at the same time and in the same step as an electrode 4022.

The electrode 4015 may be electrically connected to an FPC 4042 via an anisotropic conductive layer 4041.

The liquid crystal element 340 includes the electrode 4131, the electrode 4132, and the liquid crystal layer 4008. The alignment films 4032 and 4033 are provided so that the liquid crystal layer 4008 is positioned therebetween. The electrodes 4131 and 4132 overlap each other with the liquid crystal layer 4008 positioned therebetween. The electrode 4131 has a region overlapping the electrode 311. In addition, the electrode 4131 is electrically connected to one of a source and a drain of the transistor 4011 through the electrode 4022 and the electrode 311. The electrode 311 has a function of reflecting visible light. The electrode 4022 can be formed at the same time and in the same step as the electrode 4021.

The spacer 4035 is a columnar spacer obtained by selective etching of an insulating layer and is provided in order to control the distance between the electrode 4131 and the electrode 4132 (a cell gap). Alternatively, a spherical spacer may be used as the spacer 4035.

The display device 500c illustrated in FIG. 19 has functions of a light-emitting display device having a bottom emission structure and a reflective liquid crystal display device. Light 4520 emitted from the light-emitting element 360 is extracted through the substrate 4001. Light 4521 entering through the substrate 4001 is reflected by the electrode 311 and extracted through the substrate 4001. When the light 4521 is transmitted through the coloring layer 4134, light in a specific wavelength range is absorbed, so that the light 4521 becomes light 4522 having a wavelength range different from that of the light 4521. However, if the wavelength range of the entering light 4521 is within the wavelength range of light transmitted through the coloring layer 4134, the wavelength range of the light 4522 is almost the same as that of the light 4521.

The light 4520 may be white light or may be light having a specific wavelength range. For example, the light 4520 may have a wavelength range of red, green, blue, or the like. When the light 4520 is transmitted through the coloring layer 4134, light in a specific wavelength range may be absorbed.

### [Overcoat Layer]

For the overcoat layer 4133, an organic insulating layer of an acrylic-based resin, an epoxy-based resin, polyimide, or the like can be used. With the overcoat layer 4133, diffusion of an impurity or the like contained in the coloring layer 4134 into the transistors, the display elements, or the like can be inhibited, for example. Note that the overcoat layer 4133 is not necessarily provided, and a structure in which the overcoat layer 4133 is not formed may be employed.

### [Coloring Layer]

Examples of materials that can be used for the coloring layer include a metal material, a resin material, and a resin material containing a pigment or dye.

### [Light-Blocking Layer]

Examples of a material that can be used for the light-blocking layer include carbon black, titanium black, a metal, a metal oxide, and a composite oxide containing a solid solution of a plurality of metal oxides. The light-blocking layer may be a film containing a resin material or a thin film of an inorganic material such as a metal. Stacked films containing the material of the coloring layer can also be used for the light-blocking layer. For example, a stacked-layer structure of a film containing a material of a coloring layer which transmits light of a certain color and a film containing a material of a coloring layer which transmits light of another color can be employed. It is preferable that the coloring layer and the light-blocking layer be formed using the same material because the same manufacturing apparatus can be used and the process can be simplified.

### [Display Mode]

The display device 500c can be operated in three display modes. A first mode is a display mode for displaying an image as a reflective liquid crystal display device. A second mode is a display mode for displaying an image as a light-emitting display device. A third mode is a display mode in which the first mode and the second mode are adopted at the same time.

The first mode, in which a light source is not needed and power consumption is therefore very low, is effective in the case where external light illuminance is sufficiently high and external light is white light or light of a color close to white. The first mode is suitable for displaying text information of a book, a document, or the like, for example. Since reflected light is used, eye-friendly display which is less likely to strain eyes can be performed.

The second mode, in which an extremely vivid image (with high contrast and excellent color reproducibility) can be displayed regardless of external light illuminance and chromaticity, is effective in the case where external light illuminance is extremely low, such as at night or in a dark room, for example. When a bright image is displayed with low external light illuminance, a user may feel that the image is too bright. To prevent this, an image with reduced luminance is preferably displayed in the second mode. Thus, glare can be reduced, and power consumption can also be reduced. The second mode is suitable for displaying a vivid image, a smooth moving image, or the like.

The third mode is a display mode for displaying an image by utilizing both reflected light in the first mode and emitted light in the second mode. Specifically, reflected light in the first mode and emitted light in the second mode are combined to express one color. Accordingly, a more vivid image than that in the first mode can be displayed, and power consumption can be lower than that in the second mode. For example, the third mode is effective in the case where external light illuminance is relatively low or in the case where the chromaticity of external light is not white, such as under indoor illumination or in the morning or evening, for example. With the use of the combination of reflected light and emitted light, an image that makes a viewer feel like looking at a painting can be displayed.

### [Modification Example 1]

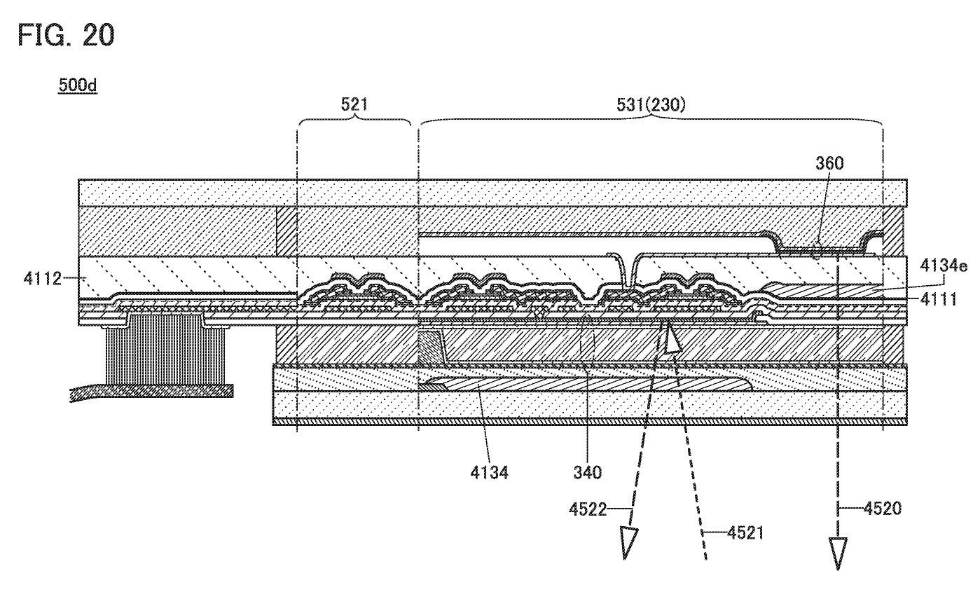

FIG. 20 is a cross-sectional view of a display device 500d illustrated as a modification example of the display device 500c. Note that differences from the display device 500c are mainly described to avoid repeated description.

The display device 500d includes a coloring layer 4134e in a region overlapping with the light-emitting element 360. Although the coloring layer 4134e in FIG. 20 is provided between the insulating layer 4111 and the insulating layer 4112, the coloring layer 4134e may be provided over any layer. A plurality of coloring layers 4134e may be stacked.

In the display device 500d, the coloring layer 4134 is not provided in the region overlapping with the light-emitting element 360.

In the display device 500c illustrated in FIG. 19, the light 4520 emitted from the light-emitting element 360 passes through the coloring layer 4134 only once. The light 4521 entering the liquid crystal element 340 after passing through the coloring layer 4134 is reflected by the electrode 311 and passes through the coloring layer 4134 again. That is, the light 4520 emitted from the light-emitting element 360 and the light 4521 reflected in the liquid crystal element 340 pass through the coloring layer different numbers of times. Therefore, it is difficult to improve display quality both in the transmissive mode and the reflective mode.

In the display device 500d, the coloring layer 4134e functions as a coloring layer for the light-emitting element 360, and the coloring layer 4134 functions as a coloring layer for the liquid crystal element 340.

Thus, the coloring layer 4134e can be designed as an optimum coloring layer for the light-emitting element 360. Therefore, color reproducibility in the transmissive mode can be improved. Similarly, the coloring layer 4134 can be designed as an optimum coloring layer for the liquid crystal element 340. Therefore, color reproducibility in the reflective mode can be improved. The coloring layer 4134 and the coloring layer 4134e can improve the display quality of the display device.

Note that in the region overlapping with the light-emitting element 360, the coloring layer 4134 may be provided so as to overlap with the coloring layer 4134e.

### [Modification Example 2]

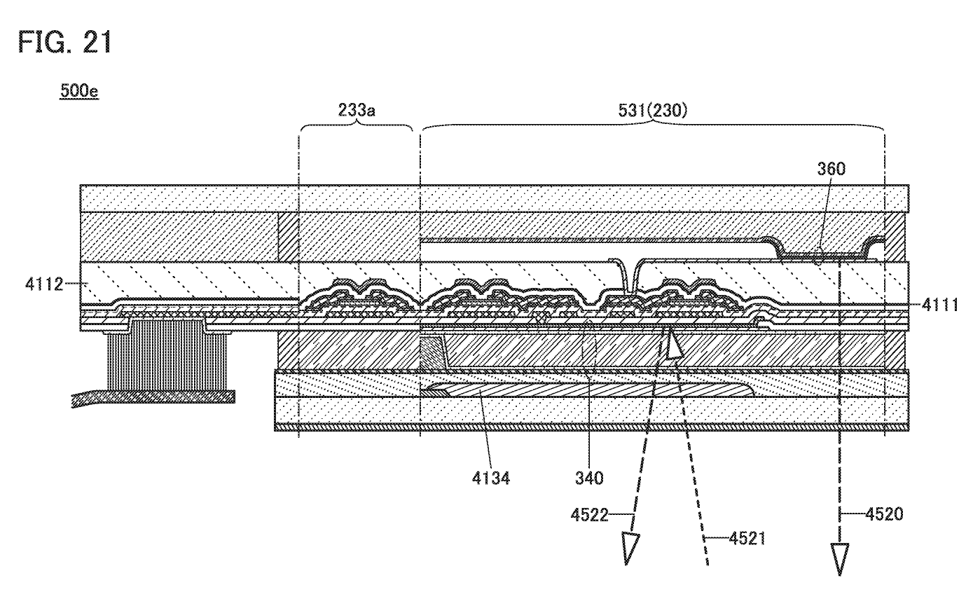

A structure in which the coloring layer 4134 is not provided in the region overlapping the light-emitting element 360 may be employed, as in the case of a display device 500e illustrated in FIG. 21. For example, the coloring layer 4134 can be omitted by using the light-emitting element 360 that emits red light, the light-emitting element 360 that emits green light, the light-emitting element 360 that emits blue light, or the like.

### Embodiment 3

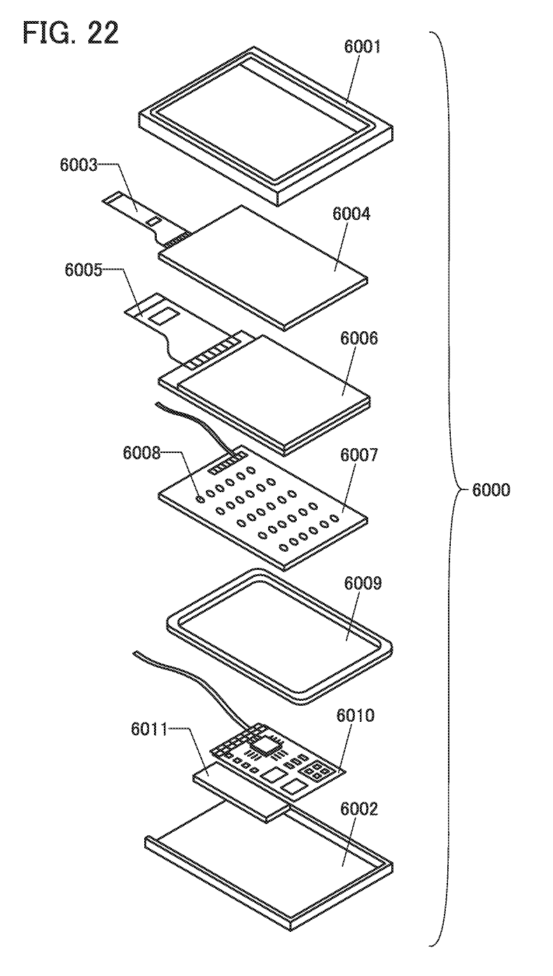

In this embodiment, a display module is described as an example of a semiconductor device using the above-described transistor. In a display module 6000 illustrated in FIG. 22, a touch sensor 6004 connected to an FPC 6003, a display panel 6006 connected to an FPC 6005, a backlight unit 6007, a frame 6009, a printed circuit board 6010, and a battery 6011 are provided between an upper cover 6001 and a lower cover 6002. Note that the backlight unit 6007, the battery 6011, the touch sensor 6004, and the like are not provided in some cases.

A semiconductor device of one embodiment of the present invention can be used, for example, for the touch sensor 6004, the display panel 6006, and an integrated circuit mounted on the printed circuit board 6010. For example, the above-described display device can be used for the display panel 6006.

The shapes and sizes of the upper cover 6001 and the lower cover 6002 can be changed as appropriate in accordance with the sizes of the touch sensor 6004, the display panel 6006, and the like.

The touch sensor 6004 can be a resistive touch panel or a capacitive touch panel and can overlap the display panel 6006. A touch sensor function can be added to the display panel 6006. For example, an electrode for a touch sensor can be provided in each pixel of the display panel 6006 so that a capacitive touch sensor function is added. Alternatively, a photosensor can be provided in each pixel of the display panel 6006 so that an optical touch sensor function is added. In the case where the touch sensor 6004 is not necessarily provided, the touch sensor 6004 can be omitted.

The backlight unit 6007 includes a light source 6008. The light source 6008 may be provided at an end portion of the backlight unit 6007, and a light diffusing plate may be used. When a light-emitting display device or the like is used for the display panel 6006, the backlight unit 6007 can be omitted.

The frame 6009 protects the display panel 6006 and functions as an electromagnetic shield for blocking electromagnetic waves generated from the printed circuit board 6010 side. The frame 6009 may also function as a radiator plate.

The printed circuit board 6010 includes a power supply circuit, a signal processing circuit for outputting a video signal and a clock signal, and the like. As a power source for supplying power to the power supply circuit, the battery 6011 or a commercial power source may be used. Note that the battery 6011 can be omitted when a commercial power source is used as the power source.

The display module 6000 can be additionally provided with a polarizing plate, a retardation plate, a prism sheet, or the like.

This embodiment can be implemented in appropriate combination with any of the structures described in the other embodiments and the like.

### Embodiment 4

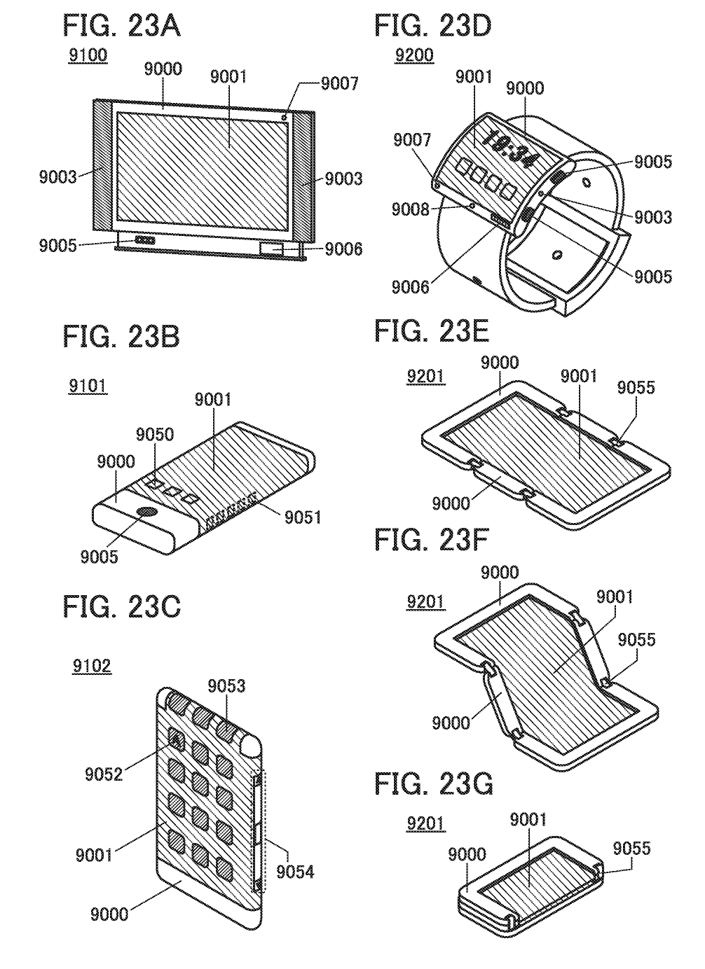

A transistor and/or a semiconductor device of one embodiment of the present invention can be used in a variety of electronic devices. FIGS. 23A to 23G illustrate examples of electronic devices including the transistor and/or the semiconductor device of one embodiment of the present invention.

Examples of electronic devices including the semiconductor device of one embodiment of the present invention are display devices of televisions, monitors, and the like; lighting devices; desktop personal computers and laptop personal computers; word processors; image reproduction devices that reproduce still images and moving images stored in recording media such as digital versatile discs (DVD); portable CD players; radios; tape recorders; headphone stereos; stereos; table clocks; wall clocks; cordless phone handsets; transceivers; mobile phones; car phones; portable game machines; tablet terminals; large-sized game machines such as pachinko machines; calculators; portable information appliances; electronic notebooks; e-book readers; electronic translators; audio input devices; video cameras; digital still cameras; electric shavers; high-frequency heating appliances such as microwave ovens; electric rice cookers; electric washing machines; electric vacuum cleaners; water heaters; electric fans; hair dryers; air-conditioning systems such as air conditioners, humidifiers, and dehumidifiers; dishwashers; dish dryers; clothes dryers; futon dryers; electric refrigerators; electric freezers; electric refrigerator-freezers; freezers for preserving DNA; flashlights; tools such as chain saws; smoke detectors; and medical equipment such as dialyzers. Other examples include industrial equipment such as guide lights, traffic lights, conveyor belts, elevators, escalators, industrial robots, power storage systems, and power storage devices for leveling the amount of power supply and smart grid.

In addition, moving objects driven by electric motors using electric power from the power storage devices are also included in the category of electronic devices. Examples of the moving objects include electric vehicles (EV), hybrid electric vehicles (HEV) that include both an internal-combustion engine and a motor, plug-in hybrid electric vehicles (PHEV), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

Electronic devices illustrated in FIGS. 23A to 23G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like.

The electronic devices illustrated in FIGS. 23A to 23G have a variety of functions. For example, the electronic devices in FIGS. 23A to 23G can have a function of displaying a variety of information (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, a function of reading out a program or data stored in a recording medium and displaying it on the display portion, and the like. Note that functions of the electronic devices in FIGS. 23A to 23G are not limited to the above, and the electronic devices can have a variety of functions. Although not illustrated in FIGS. 23A to 23G, the electronic devices may have a plurality of display portions. The electronic devices may be provided with a camera or the like and have a function of taking a still image, a function of taking a moving image, a function of storing the taken image in a memory medium (an external memory medium or a memory medium incorporated in the camera), a function of displaying the taken image on the display portion, or the like.

FIG. 23A is a perspective view of a television device 9100. The television device 9100 can include the display portion 9001 having a large screen size of, for example, 50 inches or more, or 100 inches or more.

FIG. 23B is a perspective view of a portable information appliance 9101. The portable information appliance 9101 functions as, for example, one or more of a telephone set, a notebook, and an information browsing system. Specifically, the portable information appliance can be used as a smartphone. Note that the portable information appliance 9101 may include the speaker 9003, the connection terminal 9006, the sensor 9007, or the like. The portable information appliance 9101 can display letters and image information on its plurality of surfaces. For example, three operation buttons 9050 (also referred to as operation icons, or simply icons) can be displayed on one surface of the display portion 9001. Furthermore, information 9051 indicated by dashed rectangles can be displayed on another surface of the display portion 9001. Examples of the information 9051 include display indicating reception of an incoming email, social networking service (SNS) message, call, and the like; the title and sender of an email and SNS message; the date; the time; remaining battery; and the reception strength of an antenna. Instead of the information 9051, the operation buttons 9050 or the like may be displayed on the position where the information 9051 is displayed.

FIG. 23C is a perspective view of a portable information appliance 9102. The portable information appliance 9102 has a function of displaying information on three or more surfaces of the display portion 9001. Here, information 9052, information 9053, and information 9054 are displayed on different surfaces. For example, a user of the portable information appliance 9102 can see the display (here, the information 9053) with the portable information appliance 9102 put in a breast pocket of his/her clothes. Specifically, a caller's phone number, name, or the like of an incoming call is displayed in a position that can be seen from above the portable information appliance 9102. Thus, the user can see the display without taking out the portable information appliance 9102 from the pocket and decide whether to answer the call.

FIG. 23D is a perspective view of a watch-type portable information appliance 9200. The portable information appliance 9200 is capable of executing a variety of applications such as mobile phone calls, e-mailing, viewing and editing texts, music reproduction, Internet communication, and computer games. The display surface of the display portion 9001 is curved, and images can be displayed on the curved display surface. The portable information appliance 9200 can employ near field communication based on an existing communication standard. In that case, for example, mutual communication between the portable information appliance 9200 and a headset capable of wireless communication can be performed, and thus hands-free calling is possible. The portable information appliance 9200 includes the connection terminal 9006, and data can be directly transmitted to and received from another information appliance via a connector. Power charging through the connection terminal 9006 is possible. Note that the charging operation may be performed by wireless power feeding without using the connection terminal 9006.

FIGS. 23E, 23F, and 23G are perspective views of a foldable portable information appliance 9201 that is opened, that is shifted from the opened state to the folded state or from the folded state to the opened state, and that is folded, respectively. The portable information appliance 9201 is highly portable when folded. When the portable information appliance 9201 is opened, a seamless large display region is highly browsable. The display portion 9001 of the portable information appliance 9201 is supported by three housings 9000 joined by hinges 9055. By folding the portable information appliance 9201 at a connection portion between two housings 9000 with the hinges 9055, the portable information appliance 9201 can be reversibly changed in shape from an opened state to a folded state. For example, the portable information appliance 9201 can be bent with a radius of curvature of greater than or equal to 1 mm and less than or equal to 150 mm.

This embodiment can be implemented in appropriate combination with any of the structures described in the other embodiments and the like.

### Example 1

### <Evaluation of Electrical Characteristics>

[V_{g}−I_{d} Characteristics]

The transistors 100 described in Embodiment 1 were fabricated, and V_{g}−I_{d} characteristics and field-effect mobility (μ_{FE}), which are kinds of electrical characteristics, were measured. The number of the transistors 100 subjected to the measurements was ten. The channel length L and the channel width W of each of the ten transistors 100 subjected to the measurements were 6 μm and 50 μm, respectively.

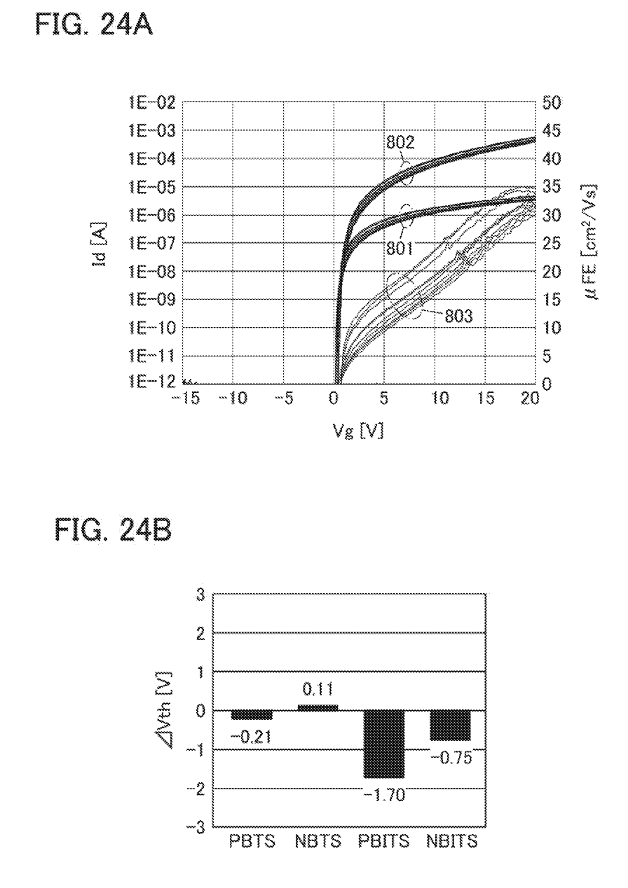

FIG. 24A shows the V_{g}−I_{d} characteristics and μ_{FE} of the ten transistors 100 subjected to the measurements. The horizontal axis in FIG. 24A represents V_{g}. One of vertical axes in FIG. 24A represents the value of a current flowing through the drain (I_{d}) on a logarithmic scale. The other vertical axis in FIG. 24A represents field-effect mobility (μ_{FE}). The gate and the back gate of the transistor 100 had the same potential.

A profile group 801 in FIG. 24A shows a change in I_{d} which was obtained when V_{d} was set to 0.1 V and V_{g} was changed from −15 V to 20 V in steps of 0.25 V. A profile group 802 shows a change in I_{d} which was obtained when V_{d} was set to 20 V and V_{g} was changed from −15 V to 20 V in steps of 0.25 V. A profile group 803 shows a change in μ_{FE} which was obtained when V_{d} was set to 20 V and V_{g} was changed from −15 V to 20 V in steps of 0.25 V.

The results in FIG. 24A indicate that the ten transistors 100 show normally-off characteristics such that I_{d} begins to increase sharply at the time when V_{g} exceeds 0 V. In addition, the ten transistors 100 have small off-state currents, and the variation among them is small. The maximum μ_{FE} of each transistor 100 is approximately 30 cm²/Vs to 35 cm²/Vs. Therefore, the transistor 100 of one embodiment of the present invention has favorable electrical characteristics.

### [BT Stress Test]

Next, four kinds of BT stress tests, i.e., PBTS, NBTS, PBITS (positive bias illumination temperature stress), and NBITS (negative bias illumination temperature stress), were performed using four transistors 100 each having a channel length L of 6 μm and a channel width W of 50 μm. One transistor was subjected to one kind of BT stress test. The amount of a change in Vₜₕ between before and after each BT stress test was examined. Note that a smaller amount of change in Vₜₕ between before and after the BT stress test indicates higher reliability of the transistor.

The amount of a change in Vₜₕ between before and after the BT stress test is preferably less than or equal to 2 V, further preferably less than or equal to 1 V, still further preferably less than or equal to 0.5 V.

In this example, for PBTS, treatment at 60° C. was performed for one hour under the conditions where the voltages of the source and the drain were set to 0 V, and V_{g} was set to +30 V. For NBTS, treatment at 60° C. was performed for one hour under the conditions where the voltages of the source and the drain were set to 0 V, and V_{g} was set to −30 V. For PBITS, treatment at 60° C. was performed for one hour under the conditions where the voltages of the source and the drain were set to 0 V, and V_{g} was set to +30 V under light irradiation with a white LED at approximately 10,000 lx. For NBITS, treatment at 60° C. was performed for one hour under the conditions where the voltages of the source and the drain were set to 0 V, and V_{g} was set to −30 V under light irradiation with a white LED at approximately 10,000 lx.

FIG. 24B shows the amount of a change in Vₜₕ between before and after each BT stress test. The amount of the change in Vₜₕ between before and after the BT stress test was −0.21 V in the PBTS, 0.11 V in the NBTS, −1.7 V in the PBITS, and −0.75 V in the NBITS. The amount of the change in Vₜₕ before and after each of the BT stress tests was less than 2 V. In particular, in the PBTS and the NBTS where light irradiation was not performed, the amount of the change in Vₜₕ was less than 0.3 V, which indicates extremely favorable results. These results show that the transistor 100 of one embodiment of the present invention has favorable reliability.

### Example 2

A transistor A was fabricated through a process where Steps 1 to 4 were different from those in the process for forming the transistor 100 described in Embodiment 1, and V_{g}−I_{d} characteristics, field-effect mobility (μ_{FE}), and V_{d}−I_{d} characteristics, which are kinds of electrical characteristics, were measured.

The transistor A has nearly the same structure as the transistor 100. The transistor A differs from the transistor 100 in that the electrode 102 is a stack in which a 100-nm-thick copper is stacked over a 10-nm-thick titanium, and the insulating layer 104 is a silicon nitride single layer. The silicon nitride layer (the insulating layer 104) was formed to a thickness of 400 nm under the conditions where the substrate temperature was 330° C., a silane gas at a flow rate of 60 sccm, a nitrogen gas at a flow rate of 1750 sccm, and an ammonia gas at a flow rate of 55 sccm were supplied as source gases to a treatment chamber of a PECVD apparatus, the pressure in the treatment chamber was controlled to 30 Pa, and a power of 1000 W was supplied using a 13.56 MHz high-frequency power source. After the formation of the silicon nitride layer, oxygen plasma treatment as Step 4 was performed in an apparatus different from the apparatus where the silicon nitride layer was formed. As the oxygen plasma treatment, plasma treatment was performed for 300 seconds under the conditions where the substrate temperature was 350° C., an oxygen gas at a flow rate of 3000 sccm was supplied to a treatment chamber, the pressure in the treatment chamber was controlled to 40 Pa, and a power of 3000 W was supplied using a 27.12 MHz high-frequency power source.

The other components of the transistor A are similar to those of the transistor 100.

### <Evaluation of Electrical Characteristics>

[V_{g}−I_{d} Characteristics]

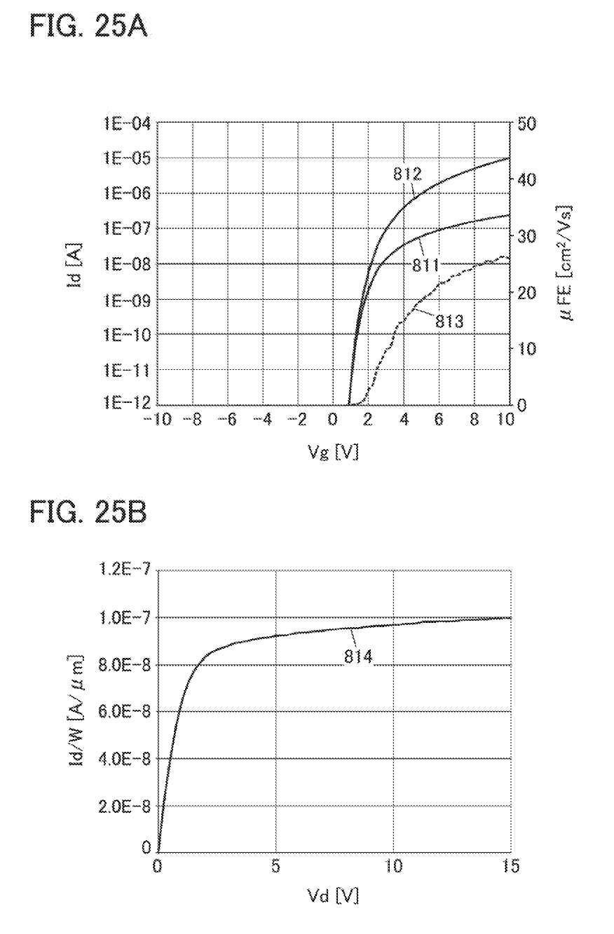

FIG. 25A shows the V_{g}−I_{d} characteristics and μ_{FE} of the transistor A. The channel length L and the channel length W of the transistor A subjected to measurement are both 3 μm.

The horizontal axis in FIG. 25A represents V_{g}. One of vertical axes in FIG. 25A represents the value of a current flowing through the drain (I_{d}) on a logarithmic scale. The other vertical axis in FIG. 25A represents field-effect mobility (μ_{FE}). In the measurement, the gate and the back gate of the transistor A had the same potential.

A profile 811 in FIG. 25A shows a change in I_{d} which was obtained when V_{d} was set to 0.1 V and V_{g} was changed from −10 V to 10 V in steps of 0.25 V. A profile 812 shows a change in I_{d} which was obtained when V_{d} was set to 20 V and V_{g} was changed from −10 V to 10 V in steps of 0.25 V. A profile 813 shows a change in μ_{FE} which was obtained when V_{d} was set to 20 V and V_{g} was changed from −10 V to 10 V in steps of 0.25 V.

The results in FIG. 25A indicate that the transistor A shows normally-off characteristics such that I_{d} begins to increase sharply at the time when V_{g} exceeds 0 V. In addition, the transistor A has a small off-state current and exhibits a μ_{FE} of approximately 26 cm²/Vs at a maximum. These results indicate that the transistor A of one embodiment of the present invention has favorable electrical characteristics.

[V_{d}−I_{d} Characteristics]

When a transistor is operated in a saturation region, it is preferable that I_{d} be less likely to change even when V_{d} changes. Measurement of V_{d}−I_{d} characteristics can reveal a change in I_{d} with respect to a change in V_{d} when a transistor is operated in a saturation region. FIG. 25B shows the V_{d}−I_{d} characteristics of the transistor A. The channel length L and the channel width W of the transistor A subjected to measurement are both 3 μm.

The horizontal axis in FIG. 25B represents V_{d}. The vertical axis in FIG. 25B represents I_{d} per micrometer of the channel width. In the measurement, the gate and the back gate of the transistor A had the same potential.

A profile 814 in FIG. 25B shows a change in I_{d} which was obtained when V_{g} was set to 3.77 V and V_{d} was changed from 0 V to 15 V in steps of 0.25 V.

The result in FIG. 25B indicates that I_{d} is less likely to change even when V_{d} changes in the transistor A of one embodiment of the present invention which is operated in a saturation region. Therefore, the transistor A of one embodiment of the present invention exhibits high saturability and has favorable electrical characteristics.

For example, when an EL element is use as a display element, a transistor for driving the EL element preferably exhibits high saturability. It is preferable that the transistor A of one embodiment of the present invention or the like be used as the transistor for driving the EL element.

### REFERENCE NUMERALS

100 transistor
101 substrate
102 electrode
103 insulating layer
104 insulating layer
105 insulating layer
106 semiconductor layer
108 insulating layer
109 insulating layer
110 insulating layer
113 insulating layer
121 electrode
181 conductive layer
182 metal oxide layer
183 metal oxide layer
184 conductive layer
185 conductive layer
186 conductive layer
187 conductive layer
192 plasma atmosphere
193 source gas
194 plasma atmosphere
195 source gas
196 plasma atmosphere
225 display element
230 pixel
311 electrode
340 liquid crystal element
360 light-emitting element

This application is based on Japanese Patent Application Serial No. 2016-145308 filed with Japan Patent Office on Jul. 25, 2016, the entire contents of which are hereby incorporated by reference.

1. A method for manufacturing a transistor, comprising:
a first step comprising a step of forming a gate electrode;
a second step comprising a step of forming a gate insulating layer over the gate electrode;
a third step comprising a step of exposing a surface of the gate insulating layer to an atmosphere containing an oxygen ion or an oxygen radical;
a fourth step comprising a step of forming a metal oxide layer over the gate insulating layer; and
a fifth step comprising a step of forming a source electrode and a drain electrode over the metal oxide layer,
wherein the gate insulating layer comprises silicon and nitrogen, and
wherein the second step and the third step are performed in one treatment chamber.

2. The method for manufacturing a transistor according to claim 1, wherein the third step is plasma treatment performed under an atmosphere containing oxygen.

3. The method for manufacturing a transistor according to claim 1, wherein the metal oxide layer comprises an oxide semiconductor.

4. The method for manufacturing a transistor according to claim 1, wherein the metal oxide layer comprises at least one of indium and zinc.

5. The method for manufacturing a transistor according to claim 1, wherein the metal oxide layer comprises a metal matrix composite.

6. A method for manufacturing a transistor, comprising:
a first step comprising a step of forming a gate electrode;
a second step comprising a step of forming a gate insulating layer over the gate electrode;
a third step comprising a step of exposing a surface of the gate insulating layer to an atmosphere containing an oxygen ion or an oxygen radical;
a fourth step comprising a step of forming a metal oxide layer over the gate insulating layer; and
a fifth step comprising a step of forming a source electrode and a drain electrode over the metal oxide layer,
wherein the gate insulating layer comprises silicon and nitrogen, and
wherein the second step and the third step are performed successively under a reduced pressure atmosphere.

7. The method for manufacturing a transistor according to claim 6, wherein the third step is plasma treatment performed under an atmosphere containing oxygen.

8. The method for manufacturing a transistor according to claim 6, wherein the metal oxide layer comprises an oxide semiconductor.

9. The method for manufacturing a transistor according to claim 6, wherein the metal oxide layer comprises at least one of indium and zinc.

10. The method for manufacturing a transistor according to claim 6, wherein the metal oxide layer comprises a metal matrix composite.

11. The method for manufacturing a transistor according to claim 6, wherein the gate electrode comprises copper.

12. A method for manufacturing a transistor, comprising:
a first step comprising a step of forming a gate electrode;
a second step comprising a step of forming a gate insulating layer over the gate electrode;
a third step comprising a step of exposing a surface of the gate insulating layer to an atmosphere containing an oxygen ion or an oxygen radical;
a fourth step comprising a step of forming a metal oxide layer over the gate insulating layer; and
a fifth step comprising a step of forming a source electrode and a drain electrode over the metal oxide layer,
wherein the gate insulating layer comprises silicon and nitrogen,
wherein the second step and the third step are performed in one treatment chamber, and
wherein the gate electrode comprises copper.

13. The method for manufacturing a transistor according to claim 12, wherein the third step is plasma treatment performed under an atmosphere containing oxygen.

14. The method for manufacturing a transistor according to claim 12, wherein the metal oxide layer comprises an oxide semiconductor.

15. The method for manufacturing a transistor according to claim 12, wherein the metal oxide layer comprises at least one of indium and zinc.

16. The method for manufacturing a transistor according to claim 12, wherein the metal oxide layer comprises a metal matrix composite.
